(19) United States
(12) Patent Application Publication
(10) Pub. No.: US 2025/0275126 A1
(43) Pub. Date: Aug. 28, 2025

(54) SEMICONDUCTOR MEMORY DEVICE AND MANUFACTURING METHOD THEREOF

(71) Applicant: Samsung Electronics Co., Ltd., Suwon-si (KR)

(72) Inventors: Seung Muk Kim, Suwon-si (KR); Hui-Jung Kim, Suwon-si (KR); Ki Seok Lee, Suwon-si (KR); Keun Nam Kim, Suwon-si (KR); Yong Kwan Kim, Suwon-si (KR); Sang Ho Lee, Suwon-si (KR); Ji Hun Lee, Suwon-si (KR)

(21) Appl. No.: 18/946,060

(22) Filed: Nov. 13, 2024

(30) Foreign Application Priority Data
Feb. 27, 2024 (KR) 10-2024-0028025

(51) Int. Cl. H10B 12/00

(52) U.S. Cl. CPC H10B 12/50; H10B 12/09; H10B 12/315

(57) ABSTRACT

A semiconductor memory device may include a first substrate region including a cell region; a second substrate region including a peripheral region that is adjacent to the cell region; a capacitor structure on the first substrate region, the capacitor structure including a lower electrode, a capacitor dielectric film extending along the lower electrode, and an upper electrode on the capacitor dielectric film; a first insulating layer on the first substrate region and in contact with a sidewall of the upper electrode; a peripheral contact plug on the second substrate region and extending in the first insulating layer; a first wiring line on the upper electrode and in contact with the upper electrode; and a second wiring line on the peripheral contact plug and in contact with the peripheral contact plug. A thickness of the first wiring line may be equal to a thickness of the second wiring line.

### CROSS-REFERENCE TO RELATED APPLICATIONS

This application claims priority from Korean Patent Application No. 10-2024-0028025 filed on Feb. 27, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to a semiconductor memory device and a manufacturing method thereof.

With the rapid development of the electronics industry along with increased user demand, electronic devices are becoming smaller and lighter. Therefore, it may be helpful for semiconductor memory elements used in the electronic devices to have a high degree of integration. Design rules for the configurations of the semiconductor memory elements are also decreasing. Therefore, there may be challenges associated with ensuring the reliability of the semiconductor memory elements.

### SUMMARY OF THE INVENTION

Aspects of the present disclosure provide a semiconductor memory device having improved product reliability.

Aspects of the present disclosure also provide a method for manufacturing a semiconductor memory device having improved product reliability.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

A semiconductor memory device according to some embodiments of the present disclosure includes a first substrate region that extends in a first direction and a second direction intersecting the first direction, the first substrate region including a cell region; a second substrate region that extends in the first and second directions, the second substrate region including a peripheral region that is adjacent to the cell region; a capacitor structure on the first substrate region, the capacitor structure including a lower electrode extending in a third direction perpendicular to an upper surface of the first substrate region, a capacitor dielectric film extending along the lower electrode, and an upper electrode on the capacitor dielectric film; a first insulating layer that is on the first substrate region and is in contact with a sidewall of the upper electrode; a peripheral contact plug that is on the second substrate region and extends in the first insulating layer in the third direction; a first wiring line that is on the upper electrode and is in contact with the upper electrode; and a second wiring line that is on the peripheral contact plug and is in contact with the peripheral contact plug, wherein a thickness of the first wiring line is equal to a thickness of the second wiring line.

A semiconductor memory device according to some embodiments of the present disclosure includes a first substrate region that extends in a first direction and a second direction intersecting the first direction, the first substrate region including a cell region; a second substrate region that extends in the first and second directions, the second substrate region including a peripheral region that is adjacent to the cell region; a capacitor structure on the first substrate region, the capacitor structure including a lower electrode extending in a third direction perpendicular to an upper surface of the first substrate region, a capacitor dielectric film extending along the lower electrode, and an upper electrode on the capacitor dielectric film; a first insulating layer that is on the first substrate region and is in contact with a sidewall of the upper electrode; a peripheral contact plug that is on the second substrate region and extends in the first insulating layer in the third direction; a first wiring line that is on the upper electrode and is in contact with the upper electrode; a second wiring line that is on the peripheral contact plug and is in contact with the peripheral contact plug; a first wiring via on the first wiring line; and a second wiring via on the second wiring line, wherein the first and second wiring lines are located at a same level as each other in the third direction relative to the upper surface of the first substrate region, and wherein the first and second wiring vias are located at a same level as each other in the third direction relative to the upper surface of the first substrate region.

A method of manufacturing a semiconductor memory device according to some embodiments of the present disclosure includes providing a substrate that extends in a first direction and a second direction intersecting the first direction, the substrate including a first region and a second region; forming a capacitor structure on the first region of the substrate, the capacitor structure including a lower electrode extending in a third direction perpendicular to an upper surface of the substrate, a capacitor dielectric film extending along the lower electrode, and an upper electrode on the capacitor dielectric film; forming a first insulating layer on the substrate, the first insulating layer contacting a sidewall of the upper electrode; forming a peripheral contact plug on the second region of the substrate, the peripheral contact plug extending in the first insulating layer in the third direction; and concurrently forming a first wiring line on the upper electrode and a second wiring line on the peripheral contact plug, wherein the first wiring line is in contact with the upper electrode, and the second wiring line is in contact with the peripheral contact plug.

A semiconductor memory device according to some embodiments of the present disclosure includes a substrate that extends in a first direction and a second direction intersecting the first direction, the substrate including a cell region and a peripheral region adjacent to the cell region; a capacitor structure on the cell region of the substrate, the capacitor structure including a lower electrode extending in a third direction perpendicular to an upper surface of the substrate, a capacitor dielectric film extending along the lower electrode, and an upper electrode on the capacitor dielectric film; a first insulating layer that is on the substrate and is in contact with a sidewall of the upper electrode; a peripheral contact plug that is on the peripheral region of the substrate and extends in the first insulating layer in the third direction; a first wiring line that is on the upper electrode and is in contact with the upper electrode; a second wiring line that is on the peripheral contact plug and is in contact with the peripheral contact plug; a first wiring via on the first wiring line; and a second wiring via on the second wiring line.

Specific details of other example embodiments are included in the detailed description and drawings.

### BRIEF DESCRIPTION OF THE DRAWINGS

The above and other aspects and features of the present disclosure will become more apparent by describing in detail example embodiments thereof with reference to the accompanying drawings, in which:

FIG. 1 is a plan view for explaining a semiconductor memory device according to some embodiments;

FIG. 2 is a cross-sectional view taken along lines A1-A1 and A2-A2 of FIG. 1;

FIG. 3 is a diagram for explaining the semiconductor memory device according to some embodiments, and corresponds to a cross-sectional view taken along lines A1-A1 and A2-A2 of FIG. 1;

FIG. 4 is a diagram for explaining the semiconductor memory device according to some embodiments, and corresponds to a cross-sectional view taken along line A1-A1 of FIG. 1;

FIG. 5 is a diagram for explaining the semiconductor memory device according to some embodiments, and corresponds to a cross-sectional view taken along line A1-A1 of FIG. 1;

FIG. 6 is a plan view for explaining the semiconductor memory device according to some embodiments;

FIG. 7 is a diagram for explaining the semiconductor memory device according to some embodiments, and corresponds to a cross-sectional view taken along line A1-A1 of FIG. 6;

FIG. 8 is a plan view for explaining the semiconductor memory device according to some embodiments;

FIG. 9 is a diagram for explaining the semiconductor memory device according to some embodiments, and corresponds to a cross-sectional view taken along line A1-A1 of FIG. 8;

FIG. 10 is a diagram for explaining the semiconductor memory device according to some embodiments, and corresponds to a cross-sectional view taken along line A1-A1 of FIG. 8;

FIG. 11 is a diagram for explaining the semiconductor memory device according to some embodiments, and corresponds to a cross-sectional view taken along line A1-A1 of FIG. 8;

FIG. 12 is a plan view for explaining the semiconductor memory device according to some embodiments;

FIG. 13 is a diagram for explaining the semiconductor memory device according to some embodiments, and corresponds to a cross-sectional view taken along line A1-A1 of FIG. 12;

FIG. 14 is a plan view for explaining the semiconductor memory device according to some embodiments;

FIG. 15 is a schematic layout diagram for explaining the semiconductor memory device according to some embodiments;

FIG. 16 is a cross-sectional view taken along line B-B of FIG. 15;

FIG. 17 is a cross-sectional view taken along line C-C of FIG. 15;

FIGS. 18 to 33 are diagrams for explaining the semiconductor memory device according to some embodiments;

FIGS. 34 to 36 are intermediate stage diagrams for explaining a method of manufacturing the semiconductor memory device according to some embodiments;

FIGS. 37 to 39 are intermediate stage diagrams for explaining a method of manufacturing the semiconductor memory device according to some embodiments; and

FIGS. 40 to 43 are intermediate stage diagrams for explaining a method of manufacturing the semiconductor memory device according to some embodiments.

### DETAILED DESCRIPTION

Example embodiments of the present disclosure will be described below with reference to the accompanying drawings.

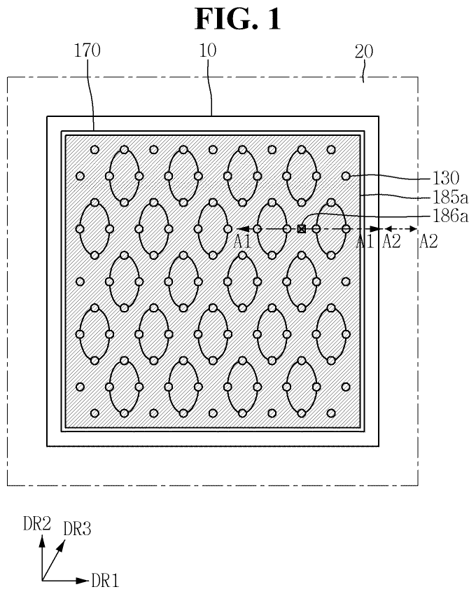

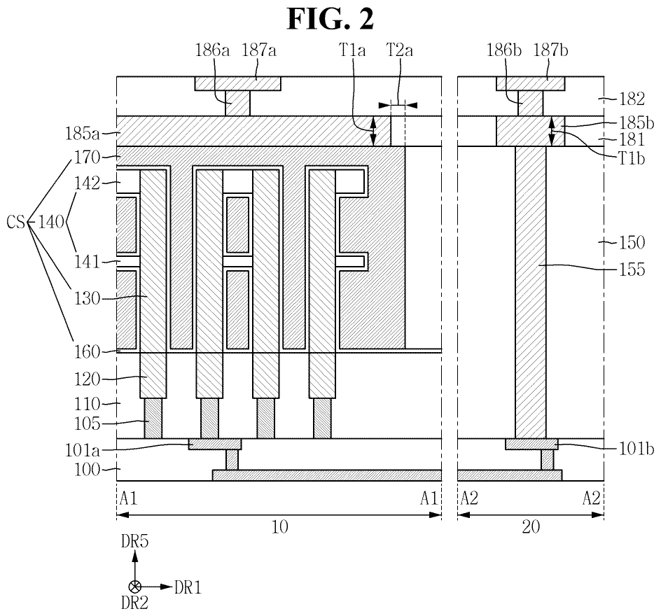

FIG. 1 is a plan view for explaining a semiconductor memory device according to some embodiments. FIG. 2 is a cross-sectional view taken along lines A1-A1 and A2-A2 of FIG. 1.

Referring to FIGS. 1 and 2, the semiconductor memory device according to some embodiments may include a substrate 100 that includes a cell pattern region 10 and a peripheral region 20. As used herein, the cell pattern region 10 may also be referred to as a cell region. The peripheral region 20 may surround the cell pattern region 10. It will be understood that “an element A surrounds an element B” (or similar language) as used herein means that the element A is at least partially around the element B but does not necessarily mean that the element A completely encloses the element B. Although not shown in FIG. 1, the peripheral region 20 may be disposed between a plurality of cell pattern regions 10 that are repeatedly disposed. The peripheral region 20 may separate a plurality of cell pattern regions 10 that are repeatedly disposed. For example, the peripheral region 20 may be adjacent to the cell pattern region 10. As used herein, a portion of the substrate 100 that includes the cell pattern region 10 may also be referred to as a first substrate region, and a portion of the substrate 100 that includes the peripheral region 20 may also be referred to as a second substrate region. In some embodiments, the first substrate region and the second substrate region may be regions of the same substrate. In other embodiments, the first substrate region and the second substrate region may be regions of different substrates. It will be understood that the substrate 100 may include a single substrate or a plurality of substrates.

The semiconductor memory device according to some embodiments may include a substrate 100, a first lower wiring line 101a, a second lower wiring line 101b, a first interlayer insulating film 110, a plurality of landing pads 120, a plurality of lower electrodes 130, an electrode support 140, a second interlayer insulating film 150, a peripheral contact plug 155, a capacitor dielectric film 160, an upper electrode 170, a third interlayer insulating film 181, a first wiring line 185a, a second wiring line 185b, a first wiring via 186a, and a second wiring via 186b.

The substrate 100 may be bulk silicon or silicon-on-insulator (SOI). In some embodiments, the substrate 100 may be a silicon substrate or may include other materials, for example, silicon germanium, silicon germanium on insulator (SGOI), indium antimonide, lead telluride, indium arsenide, indium phosphide, gallium arsenide or gallium antimonide. In the following description, the substrate 100 is described as a silicon substrate, but is not limited thereto.

The first lower wiring line 101a is disposed in the substrate 100, and may be electrically connected to the landing pad 120 and the storage contact 105, which will be described later. The second lower wiring line 101b is disposed in the substrate 100, and may be electrically connected to a peripheral contact plug 155, which will be described later. The first lower wiring line 101a and the second lower wiring line 101b may be electrically connected to each other.

The first interlayer insulating film 110 may be disposed on the substrate 100. The storage contact 105 and the landing pad 120 may be disposed in the first interlayer insulating film 110. As used herein, the first interlayer insulating film 110 may also be referred to as a first insulating layer.

The first interlayer insulating film 110 may include, for example, at least one of silicon oxide, silicon nitride, silicon oxynitride, silicon carbide, silicon carbonitride, silicon boron nitride, or a combination thereof.

The landing pad 120 may be disposed on the substrate 100. The landing pad 120 may be connected to the substrate 100. As used herein, “an element A connected to an element B” (or similar language) means that the element A is physically and/or electrically connected to the element B. The landing pads 120 may be spaced apart from each other by the first interlayer insulating film 110. A side surface of the landing pad 120 may be partially surrounded by the first interlayer insulating film 110.

The landing pad 120 may be electrically connected to a conductive region formed above or inside the substrate 100. The landing pad 120 may be connected to the substrate 100 via the storage contact 105. The landing pad 120 may be disposed on the storage contact 105.

The storage contact 105 may include, for example, at least one of an impurity-doped semiconductor material, a conductive silicide compound, a conductive metal nitride, or a metal.

The landing pad 120 may include, for example, at least one of an impurity-doped semiconductor material, a conductive silicide compound, a conductive metal nitride, or a metal. In the semiconductor memory device according to some embodiments, the landing pad 120 may include tungsten (W).

The lower electrode 130 may be disposed on the substrate 100. The lower electrode 130 may be disposed on the landing pad 120. The lower electrode 130 may be electrically connected to the landing pad 120.

For example, each of the plurality of lower electrodes 130 may have a pillar shape. The lower electrode 130 may extend longitudinally in a thickness direction of the substrate 100, that is, in a vertical direction DR5. An extending length of the lower electrode 130 in the thickness direction of the substrate 100 (i.e., the vertical direction DR5) may be longer than an extending length of the lower electrode 130 in directions DR1, DR2, and DR3 parallel to the substrate 100. For example, the vertical direction DR5 may be perpendicular to an upper surface of the substrate 100, and the directions DR1, DR2, and DR3 may be parallel to the upper surface of the substrate 100. For example, the substrate 100 may extend in the first direction DR1 and the second direction DR2. The first direction DR1 may intersect the second direction DR2.

For example, the lower electrodes 130 may be repeatedly aligned along the first direction DR1 and the second direction DR2. The first direction DR1 and the second direction DR2 may be orthogonal to each other, but are not limited thereto. The plurality of lower electrodes 130 repeatedly aligned in the first direction DR1 may also be repeatedly aligned in the second direction DR2. The plurality of lower electrodes 130 repeatedly aligned in the second direction DR2 may not be arranged linearly along the second direction DR2. The plurality of lower electrodes 130 repeatedly aligned in the second direction DR2 may be arranged in zigzags. The plurality of lower electrodes 130 may be linearly arranged along the third direction DR3.

The lower electrode 130 may include, for example, but is not limited to, a doped semiconductor material, a conductive metal nitride (e.g., titanium nitride, tantalum nitride, niobium nitride, tungsten nitride or the like), a metal (e.g., ruthenium, iridium, titanium, tantalum or the like), a conductive metal oxide (e.g., iridium oxide, niobium oxide or the like), and the like. In the semiconductor memory device according to some embodiments, the lower electrode 130 may include titanium nitride (TiN). Further, in the semiconductor memory device according to some embodiments, the lower electrode 130 may include niobium nitride (NbN).

A capacitor dielectric film 160 and an upper electrode 170 may be disposed between the lower electrodes 130. As another example, the capacitor dielectric film 160, the electrode support 140, and the upper electrode 170 may be disposed between the lower electrodes 130.

The electrode support 140 may include first and second supports 141 and 142. The electrode support 140 may be disposed to be spaced apart from each of the first interlayer insulating film 110 and the landing pad 120.

The first support 141 may be disposed on the first interlayer insulating film 110. The first support 141 may be disposed to be spaced apart from the first interlayer insulating film 110. The first support 141 may be disposed between a plurality of adjacent lower electrodes 130. The first support 141 may be in contact with the lower electrode 130.

The second support 142 may be disposed on the first support 141. The second support 142 may be disposed to be spaced apart from the first support 141. The second support 142 may be disposed between a plurality of adjacent lower electrodes 130. The second support 142 may be in contact with the lower electrode 130.

The first support 141 and the second support 142 may include an insulating material. For example, the first support 141 and the second support 142 may include at least one of silicon nitride, silicon carbonitride, silicon boron nitride, silicon oxycarbide, silicon oxynitride, silicon oxide, or silicon oxycarbonitride.

The capacitor dielectric film 160 may be formed on the lower electrode 130, the first interlayer insulating film 110, the first support 141, and the second support 142. The capacitor dielectric film 160 may extend along the profile of the lower electrode 130. The capacitor dielectric film 160 may extend along the upper and lower surfaces of the first support 141 and the upper and lower surfaces of the second support 142.

The capacitor dielectric film 160 may extend along the first interlayer insulating film 110. Specifically, the capacitor dielectric film 160 may extend along the upper surface of the first interlayer insulating film 110 between the plurality of lower electrodes 130. The capacitor dielectric film 160 may be in direct contact with the upper surface of the first interlayer insulating film 110.

The capacitor dielectric film 160 may include high dielectric constant materials including, for example, silicon oxide, silicon nitride, silicon oxynitride, and metals. Although the capacitor dielectric film 160 is shown as a single film, this is only for convenience of explanation and the present disclosure is not limited thereto.

In the semiconductor memory device according to some embodiments, the capacitor dielectric film 160 may include a stacked film structure in which zirconium oxide, aluminum oxide, and zirconium oxide are sequentially stacked.

In the semiconductor memory device according to some embodiments, the capacitor dielectric film 160 may include a dielectric film that includes hafnium (Hf). In the semiconductor memory device according to some embodiments, the capacitor dielectric film 160 may have a stacked structure of a ferroelectric material film and a paraelectric material film.

The ferroelectric material film may have ferroelectric properties. The ferroelectric material film may have a thickness to the extent of having ferroelectric properties. A thickness range of the ferroelectric material film having ferroelectric properties may vary depending on the ferroelectric material.

For example, the ferroelectric material film may include a monometal oxide. The ferroelectric material film may include a monometal oxide film. Here, the monometal oxide may be a binary compound consisting of one metal and oxygen. The ferroelectric material film having the monometal oxide may have an orthorhombic crystal system.

As an example, the metal included in the monometal oxide film may be hafnium (Hf). The monometal oxide film may be a hafnium oxide film (HfO). Here, the hafnium oxide film may have a chemical formula that is suitable for stoichiometry, or may have a chemical formula that is not suitable for stoichiometry.

As another example, the metal included in the monometal oxide film may be one of the rare earth metals belonging to lanthanoids. The monometal oxide film may be a rare earth metal oxide film belonging to the lanthanoids. Here, the rare earth metal oxide film belonging to the lanthanoids may have a chemical formula that is suitable for stoichiometry, or may have a chemical formula that is not suitable for stoichiometry. When the ferroelectric material film includes the monometal oxide film, the ferroelectric material film may have a thickness of, for example, 1 nm or more and 10 nm or less.

For example, the ferroelectric material film may include a bimetal oxide. The ferroelectric material film may include a bimetal oxide film. Here, the bimetal oxide may be a ternary compound consisting of two metals and oxygen. The ferroelectric material film including the bimetal oxide may have an orthorhombic crystal system.

The metals included in the bimetal oxide film may be, for example, hafnium (Hf) and zirconium (Zr). The bimetal oxide film may be a hafnium zirconium oxide film (HfₓZr₍₁₋ₓ₎O). In the bimetal oxide film, x may be 0.2 or more and 0.8 or less. Here, the hafnium zirconium oxide film (HfₓZr₍₁₋ₓ₎O) may have a formula that is suitable for stoichiometry, or may have a formula that is not suitable for stoichiometry.

When the ferroelectric material film includes the bimetal oxide film, the ferroelectric material film may have a thickness of, for example, 1 nm or more and 20 nm or less.

For example, the paraelectric material film may be, but is not limited to, a dielectric film containing zirconium (Zr) or a stacked film containing zirconium (Zr). Even if the chemical formulas are the same, the paraelectric material film may exhibit ferroelectric characteristics or paraelectric characteristics, depending on the crystal system of the dielectric material.

The paraelectric material may have a positive dielectric constant, and the ferroelectric material may have a negative dielectric constant in certain sections. That is, the paraelectric material may have a positive capacitance, and the ferroelectric material may have a negative capacitance.

In general, when connecting two or more capacitors having positive capacitance in series, the sum of the capacitances decreases. However, when a negative capacitor with negative capacitance and a positive capacitor with positive capacitance are connected in series, the sum of the capacitances increases.

The upper electrode 170 may be disposed on the capacitor dielectric film 160. The upper electrode 170 may extend along a profile of the capacitor dielectric film 160. The upper electrode 170 may include, for example, but is not limited to, a doped semiconductor material, a conductive metal nitride (e.g., titanium nitride, tantalum nitride, niobium nitride, tungsten nitride, etc.), a metal (e.g., ruthenium, iridium, titanium, tantalum, etc.), a conductive metal oxide (e.g., iridium oxide, niobium oxide, etc.), and the like. In the semiconductor memory device according to some embodiments, the upper electrode 170 may include titanium nitride (TiN). Further, in the semiconductor memory device according to some embodiments, the upper electrode 170 may include niobium nitride (NbN).

Although not specifically shown, the upper electrode 170 may have a single-layered structure or a multi-layered structure. When the upper electrode 170 is a single-layered structure, the upper electrode 170 may include a gap fill layer. The gap fill layer may include silicon germanium (SiGe). When the upper electrode 170 is multi-layered, the upper electrode 170 may include a gap fill layer and a low resistance layer. The gap fill layer may include silicon germanium (SiGe), and the low resistance layer may include tungsten nitride (WN). The gap fill layer may fill a narrow gap between the lower electrodes 130 without voids. The low resistance layer may lower the resistance of the upper electrode 170.

The second interlayer insulating film 150 may be disposed on the upper electrode 170. The second interlayer insulating film 150 may be on (e.g., may cover) the sidewalls of the upper electrode 170. The second interlayer insulating film 150 may be in contact with the sidewall of the upper electrode 170. The second interlayer insulating film 150 may be disposed on the first interlayer insulating film 110 and the capacitor dielectric film 160. As used herein, the second interlayer insulating film 150 may also be referred to as a second insulating layer.

The second interlayer insulating film 150 may include, for example, at least one of SiO, SiN, SiC, SiOC, SiOCH, SiON, SiBN, SiCN, or a combination thereof.

In the peripheral region 20, the peripheral contact plug 155 may penetrate (i.e., may extend in) the second interlayer insulating film 150 in a vertical direction DR5 perpendicular to the upper surface of the substrate 100. The peripheral contact plug 155 may extend in the vertical direction DR5 inside the second interlayer insulating film 150.

The peripheral contact plug 155 may include a conductive material. The peripheral contact plug 155 may include, for example, at least one of titanium nitride (TiN), tantalum nitride (TaN), copper (Cu), tungsten (W), or combinations thereof.

The third interlayer insulating film 181 may be disposed on the upper electrode 170, the second interlayer insulating film 150, and the peripheral contact plug 155. The third interlayer insulating film 181 may be on (e.g., may cover) a part (i.e., a portion) of the upper surface of the upper electrode 170. First and second wiring lines 185a and 185b, which will be described later, may be disposed in the third interlayer insulating film 181. As used herein, the third interlayer insulating film 181 may also be referred to as a third insulating layer.

The third interlayer insulating film 181 may include, for example, at least one of silicon oxide, silicon nitride, silicon oxynitride, silicon carbide, silicon carbonitride, silicon boron nitride, or a combination thereof.

The first wiring line 185a is disposed on the upper electrode 170, and may be in contact with the upper electrode 170. The second wiring line 185b is disposed on the peripheral contact plug 155, and may be in contact with the peripheral contact plug 155.

Thicknesses T1a and T1b of the first and second wiring lines 185a and 185b in the vertical direction DR5 may be equal to each other. That is, a thickness T1aof the first wiring line 185a in the vertical direction DR5 may be equal to a thickness T1b of the second wiring line 185b in the vertical direction DR5. The height of the upper surface of the upper electrode 170 may be equal to the height of the upper surface of the peripheral contact plug 155 on the basis of the vertical direction DR5. In other words, the upper surface of the upper electrode 170 may be coplanar with the upper surface of the peripheral contact plug 155. The first and second wiring lines 185a and 185b may be located at the same level. In this specification, the same level may mean that they are formed in the same process and the positions in the vertical direction DR5 are equal to each other relative to an upper surface of the substrate 100. As used herein, the term “level” refers to a height or distance in the vertical direction DR5 from the upper surface of the substrate 100. For example, a lower surface of the first wiring line 185a may be coplanar with a lower surface of the second wiring line 185b.

From a planar viewpoint, the first wiring line 185a may be disposed inside the upper electrode 170. In other words, in a plan view, the first wiring line 185a may be positioned within the upper electrode 170 (e.g., see FIG. 1). For example, in a plan view, the upper electrode 170 may surround the first wiring line 185a. The sidewall of the first wiring line 185a may be disposed on the inner side than the sidewall of the upper electrode 170 by a second length T2a. In other words, the sidewall of the first wiring line 185a may be spaced apart from the sidewall of the upper electrode 170 by a second distance T2a (e.g., in the first direction DR1). For example, the sidewall of the upper electrode 170 may protrude beyond the sidewall of the first wiring line 185a by a second distance T2a (e.g., in the first direction DR1).

The first and second wiring lines 185a and 185b may include the same material. As another example, the first and second wiring lines 185a and 185b may include different materials from each other.

Each of the first and second wiring lines 185a and 185b may include at least one of metal, metal nitride, metal oxide, metal silicide, or combinations thereof.

Each of the first and second wiring lines 185a and 185b may include, for example, at least one of tungsten (W), tungsten nitride (WN), copper (Cu), tantalum (Ta), titanium nitride (TiN), tantalum nitride (TaN), ruthenium (Ru), ruthenium nitride (RUN), molybdenum (Mo), molybdenum nitride (MoN), aluminum (Al), gold (Au), silver (Ag), platinum (Pt), carbon (C), cobalt (Co), nickel (Ni), iron (Fe), chromium (Cr), zirconium (Zr), hafnium (Hf), indium (In), gallium (Ga), zinc (Zn), manganese (Mn), niobium (Nb), magnesium (Mg), doped polysilicon, or combinations thereof.

When the first and second wiring lines 185a and 185b include doped polysilicon, each of the first and second wiring lines 185a and 185b may include, for example, at least one of boron (B), aluminum (Al), arsenic (As) or phosphorus (P).

A fourth interlayer insulating film 182 may be disposed on the third interlayer insulating film 181. The fourth interlayer insulating film 182 may include, for example, at least one of silicon oxide, silicon nitride, silicon oxynitride, silicon carbide, silicon carbonitride, silicon boron nitride, or a combination thereof. As used herein, the fourth interlayer insulating film 182 may also be referred to as a fourth insulating layer.

The first wiring via 186a may be disposed on the first wiring line 185a. The second wiring via 186b may be disposed on the second wiring line 185b. The first and second wiring vias 186a and 186b may be located at the same level. In this specification, the same level may mean that they are formed in the same process and the positions in the vertical direction DR5 are equal to each other relative to an upper surface of the substrate 100. For example, a lower surface of the first wiring via 186a may be coplanar with a lower surface of the second wiring via 186b.

From a planar viewpoint, the first wiring via 186a may be disposed inside the upper electrode 170. In other words, in a plan view, the first wiring via 186a may be positioned within the upper electrode 170 (e.g., see FIG. 1). For example, in a plan view, the upper electrode 170 may surround the first wiring via 186a. The first wiring via 186a may overlap the upper electrode 170 in the vertical direction DR5. As used herein, “an element A overlaps an element B in a direction X” (or similar language) means that there is at least one straight line that extends in the direction X and intersects both the elements A and B.

First and second wiring vias 186a and 186b and third and fourth wiring lines 187a and 187b may be disposed in the fourth interlayer insulating film 182. The first wiring line 185a may be electrically connected to the third wiring line 187a through the first wiring via 186a. The second wiring line 185b may be electrically connected to the fourth wiring line 187b through the second wiring via 186b.

Each of the first and second wiring vias 186a and 186b may include at least one of metal, conductive nitride, conductive oxide, conductive silicide, or combinations thereof.

Each of the first and second wiring vias 186a and 186b may include, for example, at least one of tungsten (W), tungsten nitride (WN), copper (Cu), tantalum (Ta), titanium nitride (TiN), tantalum nitride (TaN), ruthenium (Ru), ruthenium nitride (RuN), molybdenum (Mo), molybdenum nitride (MoN), aluminum (Al), gold (Au), silver (Ag), platinum (Pt), carbon (C), cobalt (Co), nickel (Ni), iron (Fe), chromium (Cr), zirconium (Zr), hafnium (Hf), indium (In), gallium (Ga), zinc (Zn), manganese (Mn), niobium (Nb), magnesium (Mg), doped polysilicon, or combinations thereof.

Each of the third and fourth wiring lines 187a and 187b may include at least one of metal, conductive nitride, conductive oxide, conductive silicide, or combinations thereof.

Each of the third and fourth wiring lines 187a and 187b may include, for example, at least one of tungsten (W), tungsten nitride (WN), copper (Cu), tantalum (Ta), titanium nitride (TiN), tantalum nitride (TaN), ruthenium (Ru), ruthenium nitride (RUN), molybdenum (Mo), molybdenum nitride (MoN), aluminum (Al), gold (Au), silver (Ag), platinum (Pt), carbon (C), cobalt (Co), nickel (Ni), iron (Fe), chromium (Cr), zirconium (Zr), hafnium (Hf), indium (In), gallium (Ga), zinc (Zn), manganese (Mn), niobium (Nb), magnesium (Mg), doped polysilicon, or combinations thereof.

Although FIG. 2 shows that the capacitor dielectric film 160 extends to an outer portion of the cell pattern region 10, the present disclosure is not limited thereto. For example, the capacitor dielectric film 160 may be disposed only in a region of the cell pattern region 10 in which the upper electrode 170 is formed. Unlike that shown in FIG. 2, the capacitor dielectric film 160 may be disposed only below the upper electrode 170 in the cell pattern region 10. That is, the capacitor dielectric film 160 may not be disposed up to the outer portion of the cell pattern region 10. In such a case, the second interlayer insulating film 150 may be disposed directly on the first interlayer insulating film 110 at the outer portion of the cell pattern region 10.

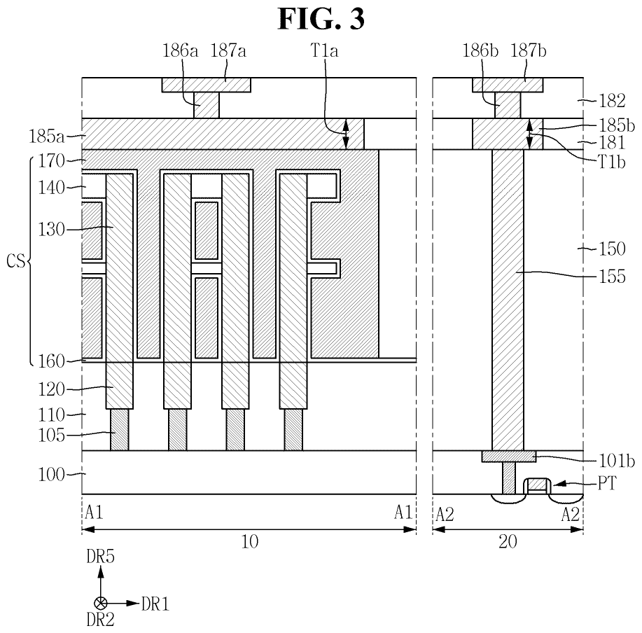

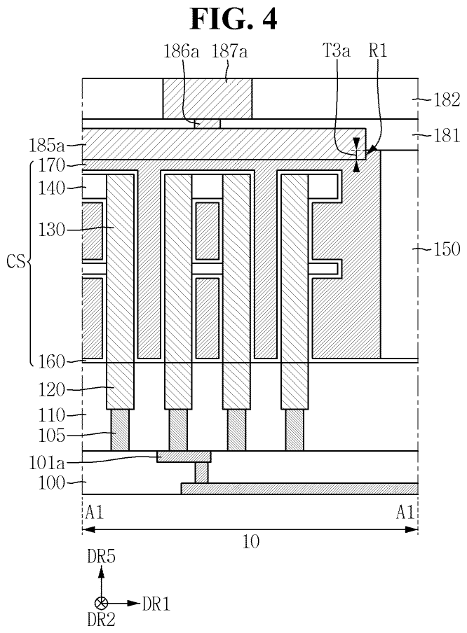

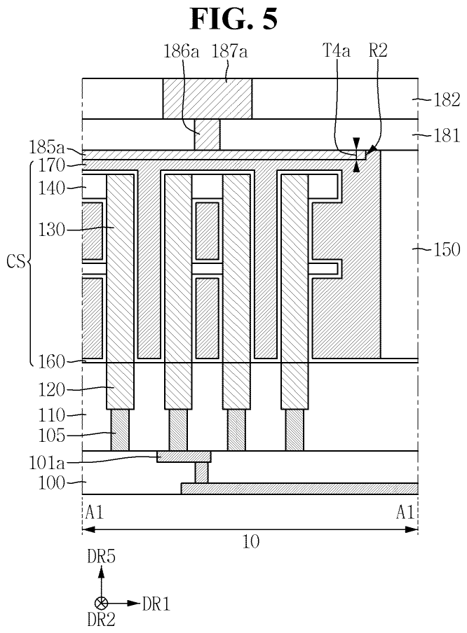

FIG. 3 is a diagram for explaining a semiconductor memory device according to some embodiments, and corresponds to a cross-sectional view taken along lines A1-A1 and A2-A2 of FIG. 1. FIG. 4 is a diagram for explaining a semiconductor memory device according to some embodiments, and corresponds to a cross-sectional view taken along line A1-A1 of FIG. 1. FIG. 5 is a diagram for explaining a semiconductor memory device according to some embodiments, and corresponds to a cross-sectional view taken along line A1-A1 of FIG. 1. For convenience of explanation, the following description will mainly focus on points that are different from those explained with reference to FIGS. 1 and 2.

Referring to FIG. 3, the semiconductor memory device according to some embodiments may further include a peripheral circuit element PT which is electrically connected to the peripheral contact plug 155 through the second lower wiring line 101b, in the substrate 100. The peripheral circuit element PT may be disposed in the peripheral region 20 of the substrate 100. The second lower wiring line 101b may include contacts and wirings electrically connected to the source/drain region of the peripheral circuit element PT.

Referring to FIG. 4, the upper electrode 170 of the semiconductor memory device according to some embodiments may include a first recess R1. The first wiring line 185a may be disposed in the first recess R1. The lower surface of the first wiring line 185a may be located at a lower level than the upper surface of the upper electrode 170 on the basis of the vertical direction DR5. For example, the lower surface of the first wiring line 185a may be closer to the substrate 100 than the upper surface of the upper electrode 170 is.

In this case, the first wiring line 185a may be disposed in the upper electrode 170 by a first depth T3a (e.g., in the vertical direction DR5). The portion of the first wiring line 185a that is not disposed in the first recess R1 may protrude above the upper electrode 170 (e.g., in the vertical direction DR5).

Referring to FIG. 5, the upper electrode 170 of the semiconductor memory device according to some embodiments may include a second recess R2. The depth of the second recess R2 in the vertical direction DR5 may be smaller than the depth of the first recess R1 (see FIG. 4), but is not limited thereto.

The first wiring line 185a may be disposed in the second recess R2. The lower surface of the first wiring line 185a may be located at a lower level than the upper surface of the upper electrode 170 on the basis of the vertical direction DR5. For example, the lower surface of the first wiring line 185a may be closer to the substrate 100 than the upper surface of the upper electrode 170 is.

In this case, the first wiring line 185a may be disposed in the upper electrode 170 by a second depth T4a (e.g., in the vertical direction DR5). The upper surface of the first wiring line 185a may be located on the same plane as (i.e., may be coplanar with) the upper surface of the upper electrode 170. For example, the first wiring line 185a may be disposed in the upper electrode 170.

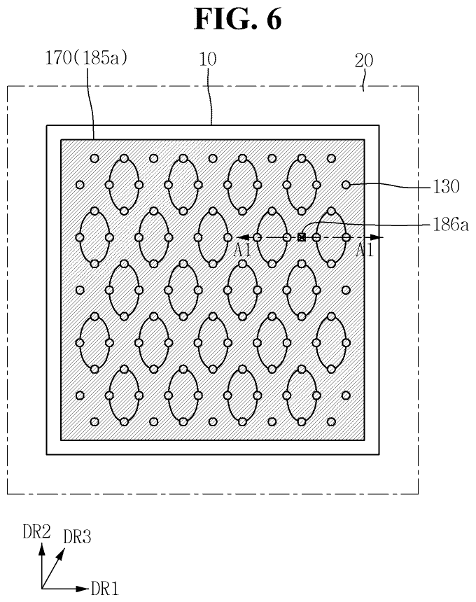

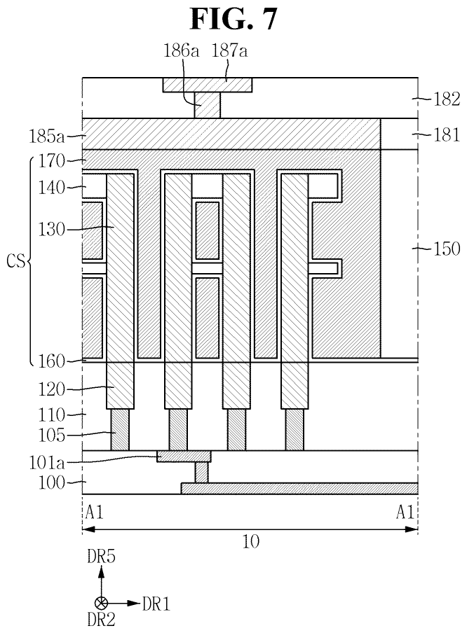

FIG. 6 is a plan view for explaining a semiconductor memory device according to some embodiments. FIG. 7 is a diagram for explaining the semiconductor memory device according to some embodiments, and corresponds to a cross-sectional view taken along line A1-A1 of FIG. 6. For convenience of explanation, the following description will mainly focus on points that are different from those explained with reference to FIGS. 1 to 5.

Referring to FIGS. 6 and 7, the first wiring line 185a may overlap the upper electrode 170 from a planar viewpoint. In other words, the first wiring line 185a may overlap the upper electrode 170 in the vertical direction DR5. A sidewall of the first wiring line 185a may be aligned with a sidewall of the upper electrode 170 in the vertical direction DR5. In other words, a sidewall of the first wiring line 185a may be coplanar with a sidewall of the upper electrode 170 in the vertical direction DR5.

On the other hand, although not specifically shown in FIGS. 6 and 7, the first wiring line 185a may not completely overlap the upper electrode 170 from a planar viewpoint point. From a planar viewpoint, a partial region of the first wiring line 185a may overlap the upper electrode 170, and the other region may not overlap the upper electrode 170. In other words, in some embodiments, a first portion of the first wiring line 185a may overlap the upper electrode 170 in the vertical direction DR5, and a second portion of the first wiring line 185a different from the first portion may not overlap the upper electrode 170 in the vertical direction DR5.

In this case, only one of the sidewalls of the first wiring line 185a may be aligned on the same side surface as (i.e., may be coplanar with) the sidewall of the upper electrode 170 in the vertical direction DR5. That is, the other sidewall of the first wiring line 185a may not be aligned with (i.e., may not be coplanar with) the sidewall of the upper electrode 170 in the vertical direction DR5.

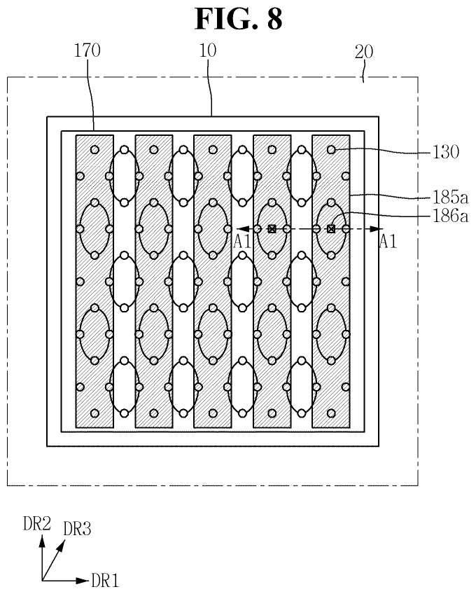

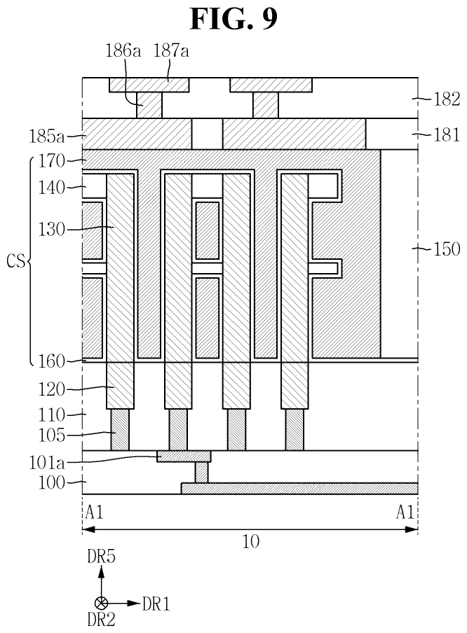

FIG. 8 is a plan view for explaining a semiconductor memory device according to some embodiments. FIG. 9 is a diagram for explaining the semiconductor memory device according to some embodiments, and corresponds to a cross-sectional view taken along line A1-A1 of FIG. 8. For convenience of explanation, the following description will mainly focus on points that are different from those explained with reference to FIGS. 1 to 7.

Referring to FIGS. 8 and 9, from a planar viewpoint, the first wiring lines 185a may be formed of a plurality of lines extending in the second direction DR2 and spaced apart from each other in the first direction DR1. The first wiring lines 185a may be disposed on the upper electrode 170 to be spaced apart from each other. Accordingly, the first wiring vias 186a connected to the first wiring line 185a may also be disposed on the upper electrode 170 to be spaced apart from each other in the first direction DR1.

An interval by which the first wiring lines 185a are spaced apart from each other, the number of first wiring lines 185a, the shape of the first wiring lines 185a, and the like are not limited to those shown in FIGS. 8 and 9.

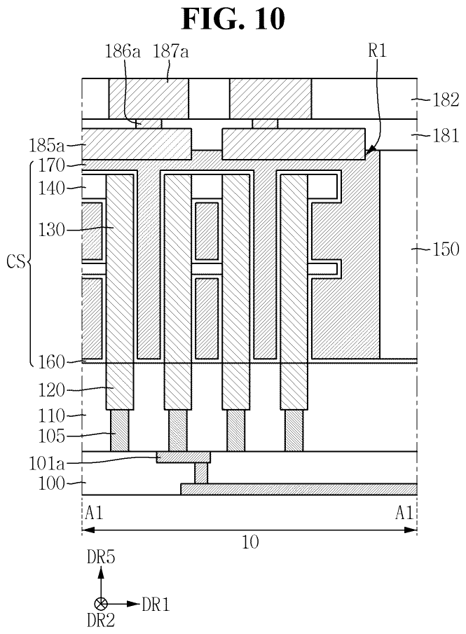

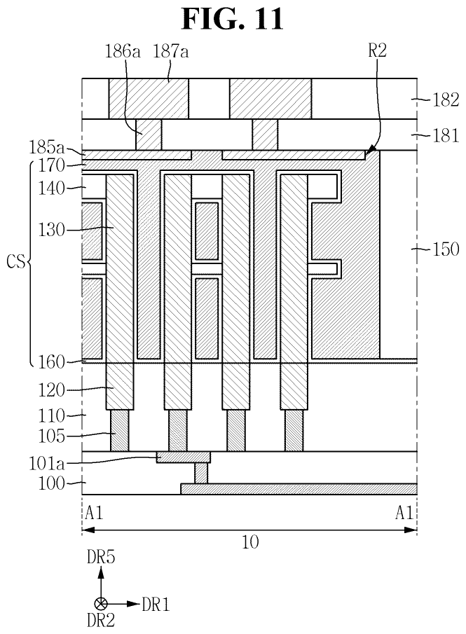

FIG. 10 is a diagram for explaining the semiconductor memory device according to some embodiments, and corresponds to a cross-sectional view taken along line A1-A1 of FIG. 8. FIG. 11 is a diagram for explaining the semiconductor memory device according to some embodiments, and corresponds to a cross-sectional view taken along line A1-A1 of FIG. 8. For convenience of explanation, the following description will mainly focus on points that are different from those explained with reference to FIGS. 1 to 9.

Referring to FIG. 10, an upper electrode 170 of the semiconductor memory device according to some embodiments may include a first recess R1. The first wiring line 185a may be disposed in the first recess R1. The lower surface of the first wiring line 185a may be located at a lower level than the upper surface of the upper electrode 170 on the basis of the vertical direction DR5. For example, the lower surface of the first wiring line 185a may be closer to the substrate 100 than the upper surface of the upper electrode 170 is.

A portion of the first wiring line 185a that is not disposed in the first recess R1 may protrude above the upper electrode 170 (e.g., in the vertical direction DR5).

Referring to FIG. 11, the upper electrode 170 of the semiconductor memory device according to some embodiments may include a second recess R2. A depth of the second recess R2 in the vertical direction DR5 may be smaller than a depth of the first recess R1 (see FIG. 10), but is not limited thereto.

The first wiring line 185a may be disposed in the second recess R2. The lower surface of the first wiring line 185a may be located at a lower level than the upper surface of the upper electrode 170 on the basis of the vertical direction DR5. For example, the lower surface of the first wiring line 185a may be closer to the substrate 100 than the upper surface of the upper electrode 170 is.

The upper surface of the first wiring line 185a may be located on the same plane as (i.e., may be coplanar with) the upper surface of the upper electrode 170. For example, the first wiring line 185a may be disposed in the upper electrode 170.

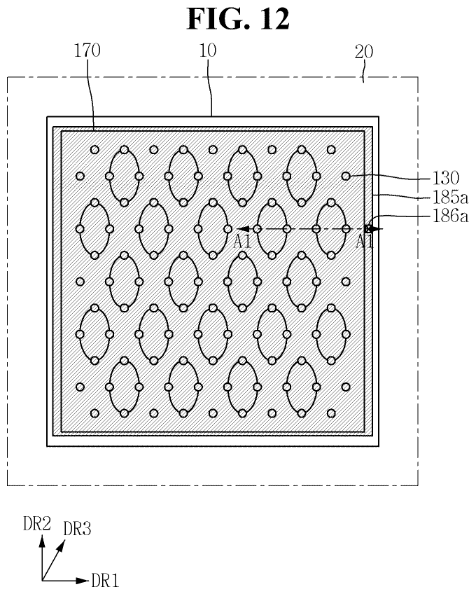

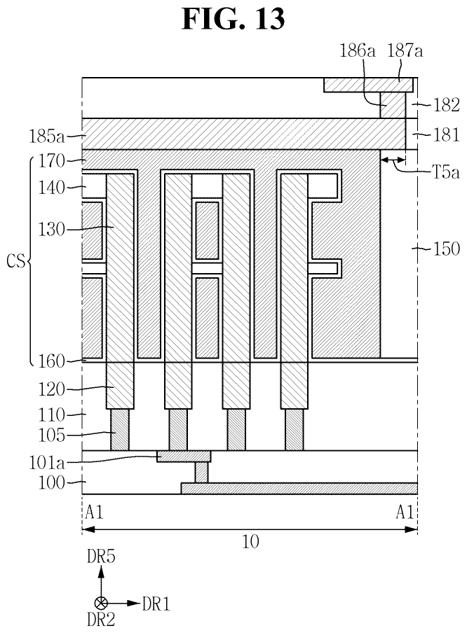

FIG. 12 is a plan view for explaining the semiconductor memory device according to some embodiments. FIG. 13 is a diagram for explaining the semiconductor memory device according to some embodiments, and corresponds to a cross-sectional view taken along line A1-A1 of FIG. 12. For convenience of explanation, the following description will mainly focus on points that are different from those explained with reference to FIGS. 1 to 11.

Referring to FIGS. 12 and 13, the first wiring line 185a may be disposed outside the upper electrode 170 from a planar viewpoint. In other words, in a plan view, at least a portion of the first wiring line 185a may be positioned adjacent to, but outside of, the upper electrode 170 (e.g., see FIG. 12). For example, in a plan view, the first wiring line 185a may surround the upper electrode 170. At least a portion of the first wiring line 185a may not overlap the upper electrode 170 in the vertical direction DR5. The sidewall of the first wiring line 185a may protrude beyond the sidewall of the upper electrode 170 by a fifth length T5a (e.g., in the first direction DR1). In this case, from a planar viewpoint, the first wiring via 186a may be disposed outside the upper electrode 170. For example, the first wiring via 186a may not overlap the upper electrode 170 in the vertical direction DR5.

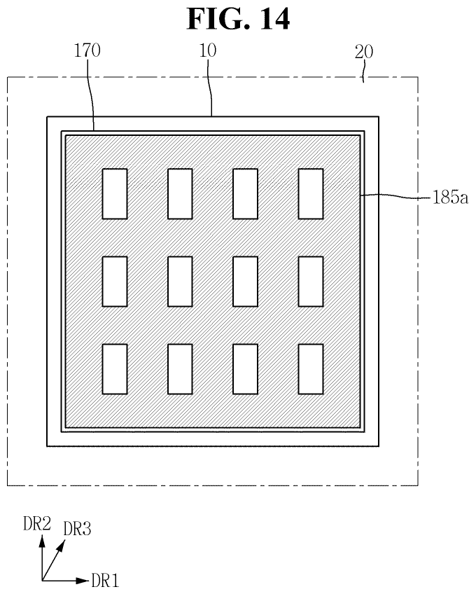

FIG. 14 is a plan view for explaining the semiconductor memory device according to some embodiments. For convenience of explanation, the following description will mainly focus on points that are different from those explained with reference to FIGS. 1 to 13.

Referring to FIG. 14, from a planar viewpoint, the first wiring line 185a may be formed in a mesh shape. From a planar viewpoint, the first wiring line 185a may have a shape having a plurality of internal spaces spaced apart from each other. The interval by which the first wiring lines 185a are spaced apart, the size of the internal space, the shape, and the like are not limited to those shown in FIG. 14.

The shape of the first wiring line 185a is not limited to that shown in FIG. 14. From a planar viewpoint, the first wiring line 185a may have a linear shape. From a planar viewpoint, the first wiring line 185a may have a shape in which shapes extending in the first direction DR1 and spaced apart in the second direction DR2 is mixed with shapes extending in the second direction DR2 and spaced apart in the first direction DR1. As another example, from a planar viewpoint, the first wiring line 185a may have a shape extending in the diagonal direction (e.g., the third direction DR3).

In some embodiments, from a planar viewpoint, the first wiring line 185a may be of an “L” type, an “I” type, or an “H” type. That is, in a plan view, the first wiring line 185a may have an “L” shape, an “I” shape, or an “H” shape. As another example, from a planar viewpoint, the first wiring line 185a may have a shape in which a bridge shape is added to the above-mentioned “H” shape.

From a planar viewpoint, the first wiring line 185a may have a curved shape. From a planar viewpoint, the first wiring line 185a may have a circular shape, an elliptical shape, a sector shape or a semicircular shape in which a circle is quartered or bisected.

From a planar viewpoint, the first wiring line 185a may have a polygonal shape such as a triangle, a quadrangle or a pentagon. From a planar viewpoint, the first wiring line 185a may have an island pattern type shape in which a plurality of rectangles, circles, and the like are spaced apart. As another example, from a planar viewpoint, the first wiring line 185a may have a donut shape with an empty interior. That is, the first wiring line 185a may be formed into various shapes depending on the patterning process, taking into consideration the resistance characteristics.

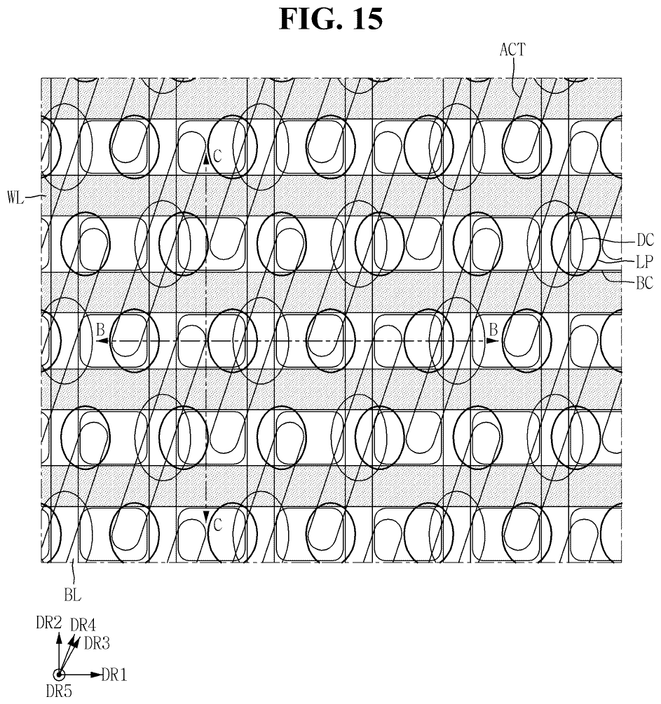

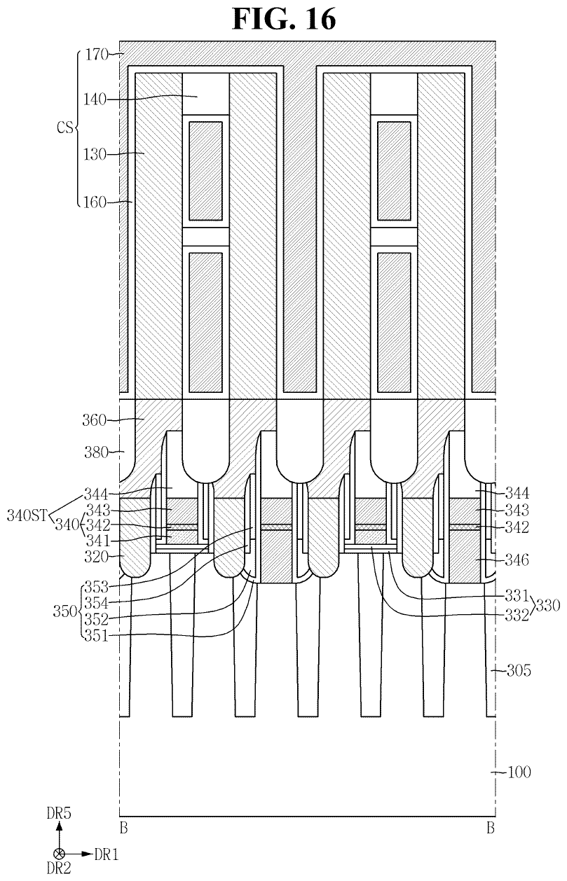

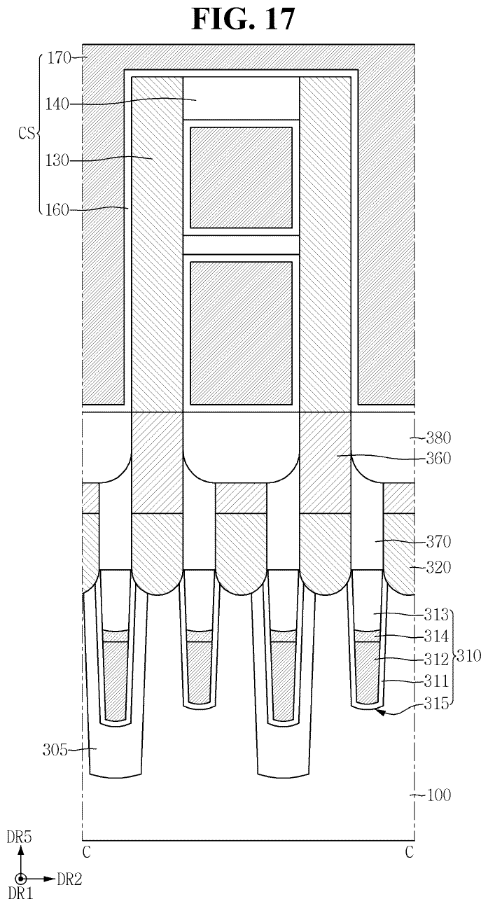

FIG. 15 is a schematic layout diagram for explaining the semiconductor memory device according to some embodiments. FIG. 16 is a cross-sectional view taken along line B-B of FIG. 15. FIG. 17 is a cross-sectional view taken along line C-C of FIG. 15.

Although FIG. 15 shows an example layout diagram of a Dynamic Random-Access Memory (DRAM) device except for the capacitor structure CS, the present disclosure is not limited thereto. The first direction DR1 and the second direction DR2 of FIG. 15 may be, but are not limited to, the first direction DR1 and the second direction DR2 of FIG. 1. In some embodiments, the first direction DR1 of FIG. 15 may correspond to the second direction DR2 of FIG. 1, and the second direction DR2 of FIG. 15 may correspond to the first direction DR1 of FIG. 1.

Referring to FIG. 15, a semiconductor memory device according to some embodiments may include a plurality of active regions ACT. The active region ACT may be defined by an element isolation film (305 of FIG. 16) formed in the substrate (100 of FIG. 16).

As the design rule of the semiconductor memory device decreases, the active region ACT may be disposed in the form of a bar of a diagonal line or an oblique line, as shown. The active region ACT may have a bar shape extending in a fourth direction DR4.

A plurality of gate electrodes may be disposed on the active region ACT in the first direction DR1 across the active region ACT. The plurality of gate electrodes may extend parallel to each other. The plurality of gate electrodes may be, for example, a plurality of word lines WL.

The word lines WL may be disposed at regular intervals. A width of the word lines WL or an interval between the word lines WL may be determined depending on design rules.

A plurality of bit lines BL extending in the second direction DR2 orthogonal to the word line WL may be disposed on the word line WL. The plurality of bit lines BL may extend parallel to each other.

The bit lines BL may be disposed at regular intervals. A width of the bit lines BL or an interval between the bit lines BL may be determined depending on design rules.

The semiconductor memory device according to some embodiments may include various contact arrangements formed on the active region ACT. Various contact arrangements may include, for example, a direct contact DC, a buried contact BC, a landing pad LP, and the like.

Here, the direct contact DC may refer to a contact that electrically connects the active region ACT to the bit line BL. The buried contact BC may refer to a contact that connects the active region ACT to a lower electrode (130 of FIG. 16) of the capacitor structure (CS of FIG. 16).

In view of the placement structure, a contact area between the buried contact BC and the active region ACT may be small. Therefore, a conductive landing pad LP may be introduced to enlarge the contact area with the active region ACT and enlarge the contact area with the lower electrode (130 of FIG. 16) of the capacitor structure (CS of FIG. 16).

The landing pad LP may be disposed between the active region ACT and the buried contact BC, or may be disposed between the buried contact BC and the lower electrode (130 of FIG. 16) of the capacitor structure (CS of FIG. 16). By enlarging the contact area through the introduction of the landing pad LP, the contact resistance between the active region ACT and the lower electrode (130 of FIG. 16) may decrease.

In the semiconductor memory device according to some embodiments, the direct contact DC may be disposed in a central portion of the active region ACT. The buried contact BC may be disposed at both (i.e., opposing) ends of the active region ACT.

Since the buried contacts BC are disposed at both ends of the active region ACT, the landing pads LP may be disposed adjacent to both ends of the active region ACT to partially overlap the buried contacts BC.

In other words, the buried contact BC may be formed to overlap the active region ACT and the element isolation film (305 of FIG. 16) between the adjacent word lines WL and between the adjacent bit lines BL.

The word lines WL may be formed in a structure buried in the substrate 100. The word line WL may be disposed across the active region ACT between the direct contact DC and the buried contact BC.

As shown, two word lines WL may be disposed across one active region ACT. Since the active regions ACT is disposed in an oblique line shape, the word lines WL may have an angle less than 90 degrees with respect to the active region ACT.

The direct contact DC and the buried contact BC may be disposed symmetrically. Therefore, the direct contact DC and the buried contact BC may be disposed on a straight line along the first direction DR1 and the third direction DR3.

On the other hand, unlike the direct contact DC and the buried contact BC, the landing pads LP may be disposed in zigzags in the second direction DR2 in which the bit lines BL extend. Also, the landing pad LP may be disposed to overlap the same side surface portion of each bit line BL in the first direction DR1 in which the word lines WL extend.

For example, each of the landing pads LP of a first line may overlap a left side surface of the corresponding bit line BL, and each of the landing pads LP of a second line may overlap a right side surface of the corresponding bit line BL.

Referring to FIGS. 15 to 17, the semiconductor memory device according to some embodiments may include a gate structure 310, a plurality of bit line structures 340ST, a storage contact 320, and a capacitor structure CS.

The element isolation film 305 may be formed in the substrate 100. The element isolation film 305 may have a shallow trench isolation (STI) structure with excellent element isolation characteristics. The element isolation film 305 may define the active region ACT on the substrate 100.

The active region ACT defined by the element isolation film 305 may have an island shape including a minor axis and a major axis, as shown in FIG. 15. The active region ACT may have a form of an oblique line to have an angle less than 90 degrees with respect to the word line WL formed in the element isolation film 305.

The element isolation film 305 may include, for example, but is not limited to, at least one of a silicon oxide film, a silicon nitride film, or a silicon oxynitride film. Although the element isolation film 305 is shown as being formed as a single insulating film, this is merely for convenience of explanation, and the present disclosure is not limited thereto. Depending on the width of the element isolation film 305, the element isolation film 305 may be formed as a single insulating film or may be formed as a plurality of insulating films.

Further, the active region ACT may have an oblique line shape to have an angle less than 90 degrees with respect to the bit line BL formed on the element isolation film 305. That is, the active region ACT may extend in a fourth direction DR4 having a predetermined angle with respect to the first direction DR1 and the second direction DR2.

The gate structure 310 may be formed in the substrate 100 and the element isolation film 305. The gate structure 310 may be formed across the element isolation film 305 and the active region ACT defined by the element isolation film 305. The gate structure 310 may include a gate trench 315, a gate insulating film 311, a gate electrode 312, a gate capping pattern 313 and a gate capping conductive film 314 which are formed in the substrate 100 and the element isolation film 305. Here, the gate electrode 312 may correspond to the word line WL. Unlike the shown example, in some embodiments, the gate structure 310 may not include the gate capping conductive film 314.

The gate insulating film 311 may extend along sidewalls and a bottom surface of the gate trench 315. The gate insulating film 311 may extend along a profile of at least a part of the gate trench 315.

The gate insulating film 311 may include, for example, at least one of silicon oxide, silicon nitride, silicon oxynitride or a high dielectric constant material having a higher dielectric constant than that of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof.

The gate electrode 312 may be formed on the gate insulating film 311. The gate electrode 312 may fill a part of the gate trench 315. The gate capping conductive film 314 may extend along the upper surface of the gate electrode 312.

The gate electrode 312 may include at least one of a metal, a metal alloy, a conductive metal nitride, a conductive metal carbonitride, a conductive metal carbide, a metal silicide, a doped semiconductor material, a conductive metal oxynitride, or a conductive metal oxide. The gate electrode 312 may include, for example, but is not limited to, at least one of TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, RuOx or combinations thereof. The gate capping conductive film 314 may include, for example, but is not limited to, polysilicon or polysilicon germanium.

The gate capping pattern 313 may be disposed on the gate electrode 312 and the gate capping conductive film 314. The gate capping pattern 313 may fill the portion of the gate trench 315 that remains after the gate electrode 312 and the gate capping conductive film 314 are formed. Although the gate insulating film 311 is shown to extend along the sidewalls of the gate capping pattern 313, the present disclosure is not limited thereto. The gate capping pattern 313 may include, for example, at least one of silicon nitride (SiN), silicon oxynitride (SiON), silicon oxide (SiO₂), silicon carbonitride (SiCN), silicon oxycarbonitride (SiOCN), or combinations thereof.

Although it is not shown, an impurity doping region may be formed on at least one side of the gate structure 310. The impurity doping region may be a source/drain region of a transistor.

A bit line structure 340ST may include a cell conductive line 340 and a cell line capping film 344. The cell conductive line 340 may be formed on the substrate 100 and the element isolation film 305 on which the gate structure 310 is formed. The cell conductive line 340 may intersect the element isolation film 305 and the active region ACT. The cell conductive line 340 may be formed to intersect the gate structure 310. Here, the cell conductive line 340 may correspond to a bit line BL.

The cell conductive line 340 may be multiple films. The cell conductive line 340 may include, for example, a first cell conductive film 341, a second cell conductive film 342, and a third cell conductive film 343. The first to third cell conductive films 341, 342, and 343 may be sequentially stacked on the substrate 100 and the element isolation film 305. Although the cell conductive line 340 is shown as a triple film, the present disclosure is not limited thereto.

Each of the first to third cell conductive films 341, 342, and 343 may include, for example, at least one of an impurity-doped semiconductor material, a conductive silicide compound, a conductive metal nitride, a metal, or a metal alloy. For example, the first cell conductive film 341 may include a doped semiconductor material, the second cell conductive film 342 may include at least one of a conductive silicide compound or a conductive metal nitride, and the third cell conductive film 343 may include at least one of metal or metal alloy. However, the present disclosure is not limited thereto.

A bit line contact 346 may be formed between the cell conductive line 340 and the substrate 100. That is, the cell conductive line 340 may be formed on the bit line contact 346. For example, the bit line contact 346 may be formed at a point in which the cell conductive line 340 intersects a central portion of the active region ACT having an island shape.

The bit line contact 346 may electrically connect the cell conductive line 340 and the substrate 100. Here, the bit line contact 346 may correspond to the direct contact DC. The bit line contact 346 may include, for example, at least one of an impurity-doped semiconductor material, a conductive silicide compound, a conductive metal nitride, or a metal.

Referring to FIG. 16, the cell conductive line 340 may include a second cell conductive film 342 and a third cell conductive film 343 in a region that overlaps the upper surface of the bit line contact 346. The cell conductive line 340 may include first to third cell conductive films 341, 342, and 343 in a region that does not overlap the upper surface of the bit line contact 346.

A cell line capping film 344 may be disposed on the cell conductive line 340. The cell line capping film 344 may extend along the upper surface of the cell conductive line 340 in the second direction DR2. At this time, the cell line capping film 344 may include, for example, at least one of a silicon nitride film, a silicon oxynitride film, a silicon carbonitride film, or a silicon oxycarbonitride film. In the semiconductor memory device according to some embodiments, the cell line capping film 344 may include, for example, a silicon nitride film. Although the cell line capping film 344 is shown as being a single film, the present disclosure is not limited thereto. The cell line capping film 344 may be multiple films. However, if each film constituting the multiple film is the same material, the cell line capping film 344 may be considered a single film.

The cell insulating film 330 may be formed on the substrate 100 and the element isolation film 305. More specifically, the cell insulating film 330 may be formed on the substrate 100 and the element isolation film 305 on which the bit line contact 346 is not formed. The cell insulating film 330 may be formed between the substrate 100 and the cell conductive line 340, and between the element isolation film 305 and the cell conductive line 340.

The cell insulating film 330 may be a multiple film including the first cell insulating film 331 and the second cell insulating film 332. For example, the first cell insulating film 331 may include a silicon oxide film, and the second cell insulating film 332 may include a silicon nitride film, but the present disclosure is not limited thereto. Although not shown, in some embodiments, the cell insulating film 330 may be a single film.

A cell line spacer 350 may be disposed on sidewalls of the cell conductive line 340 and the cell line capping film 344. The cell line spacer 350 may be formed on the substrate 100 and the element isolation film 305 at a portion of the cell conductive line 340 in which the bit line contact 346 is formed. The cell line spacer 350 may be disposed on sidewalls of the cell conductive line 340, the cell line capping film 344 and the bit line contact 346.

The cell line spacer 350 may be disposed on the cell insulating film 330 in the remaining portions of the cell conductive line 340 in which the bit line contact 346 is not formed. The cell line spacer 350 may be disposed on the sidewalls of the cell conductive line 340 and the cell line capping film 344.

The cell line spacer 350 may be a multiple film including first to fourth cell line spacers 351, 352, 353, and 354. For example, the first to fourth cell line spacers 351, 352, 353, and 354 may include, but are not limited to, one of a silicon oxide film, a silicon nitride film, a silicon oxynitride film (SiON), a silicon oxycarbonitride film (SiOCN), air, or combinations thereof. Although not shown, in some embodiments, the cell line spacer 350 may be a single film.

Referring to FIGS. 15 to 17, for example, the second cell line spacer 352 may not be disposed on the cell insulating film 330, but may be disposed on the sidewall of the bit line contact 346. On the upper surface of the gate structure 310, the fourth cell line spacer 354 may extend along the sidewalls of the cell conductive lines 340 adjacent to each other in the first direction DR1 and along the upper surface of the gate capping pattern 313.

A fence pattern 370 may be disposed on the substrate 100 and the element isolation film 305. The fence pattern 370 may be formed to overlap the gate structure 310 formed in the substrate 100 and the element isolation film 305. The fence pattern 370 may be disposed between the bit line structures 340ST extending in the second direction DR2. The fence pattern 370 may include, for example, at least one of silicon oxide, silicon nitride, silicon oxynitride, or combinations thereof.

The storage contact 320 may be disposed between the bit lines BL adjacent in the first direction DR1. Specifically, the storage contact 320 may be disposed between the cell conductive lines 340 adjacent in the first direction DR1. The storage contact 320 may be disposed between the fence patterns 370 adjacent in the second direction DR2. The storage contact 320 may overlap the substrate 100 and the element isolation film 305 between adjacent cell conductive lines 340. The storage contact 320 may be connected to the active region ACT. Here, the storage contact 320 may correspond to the buried contact BC. Furthermore, the storage contact 320 may correspond to the storage contact 105 of FIG. 2.

The storage contact 320 may include, for example, at least one of an impurity-doped semiconductor material, a conductive silicide compound, a conductive metal nitride, or a metal.

A landing pad 360 may be formed on the storage contact 320. The landing pad 360 may be electrically connected to the storage contact 320. The landing pad 360 may be connected to the active region ACT. The landing pad 360 may correspond to the landing pad LP of FIG. 15. Additionally, the landing pad 360 may correspond to the landing pad 120 of FIG. 2.

The landing pad 360 may overlap a part of the upper surface of the bit line structure 340ST. The landing pad 360 may include, for example, at least one of an impurity-doped semiconductor material, a conductive silicide compound, a conductive metal nitride, a conductive metal carbide, a metal, or a metal alloy.

A pad isolation insulating pattern 380 may be formed on the landing pad 360 and the bit line structure 340ST. For example, the pad isolation insulating pattern 380 may be disposed on the cell line capping film 344. The pad isolation insulating pattern 380 may define a landing pad 360 that forms a plurality of isolation regions. The pad isolation insulating pattern 380 may correspond to the first interlayer insulating film 110 of FIG. 2.

The pad isolation insulating pattern 380 may not be on (e.g., may not cover) the upper surface of the landing pad 360. For example, the height of the upper surface of the landing pad 360 may be lower than the height of the upper surface of the pad isolation insulating pattern 380, on the basis of the upper surface of the substrate 100.

The pad isolation insulating pattern 380 may include an insulating material. The pad isolation insulating pattern 380 may electrically isolate the plurality of landing pads 360 from each other. The pad isolation insulating pattern 380 may include, for example, at least one of a silicon oxide film, a silicon nitride film, a silicon oxynitride film, a silicon oxycarbonitride film, or a silicon carbonitride film.

The capacitor dielectric film 160 may extend along the upper surface of the pad isolation insulating pattern 380. The capacitor dielectric film 160 may be in direct contact with the upper surface of the pad isolation insulating pattern 380.

The capacitor structure CS may be disposed on the landing pad 360. The capacitor structure CS may be connected to the landing pad 360. That is, the capacitor structure CS may be electrically connected to the storage contact 320.

The capacitor structure CS may include a lower electrode 130, a capacitor dielectric film 160, and an upper electrode 170. A support 140 that supports the lower electrode 130 may be formed on the pad isolation insulating pattern 380.

Explanation of the landing pad 360 connected to the capacitor structure CS, and the lower electrode 130, the support 140, the capacitor dielectric film 160, and the upper electrode 170 included in the capacitor structure CS may be substantially the same as that explained with reference to FIG. 2.

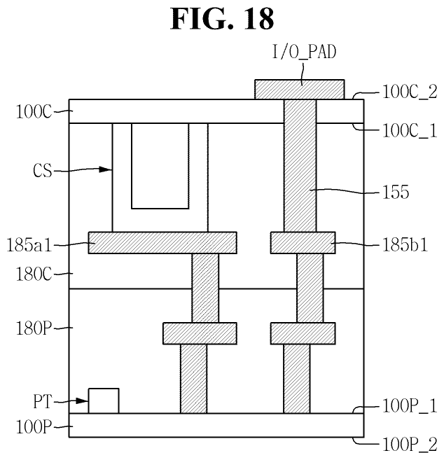

FIGS. 18 to 33 are diagrams for explaining a semiconductor memory device according to some embodiments. For convenience of explanation, the following description will mainly focus on points that are different from those explained with reference to FIGS. 1 to 17.

Referring to FIGS. 18 to 33, the semiconductor memory device according to some embodiments may include a cell substrate 100C, a capacitor structure CS, a cell insulating film 180C, a peripheral substrate 100P, a peripheral circuit element PT, a peripheral insulating film 180P, a peripheral contact plug 155, first and second wiring lines 185a1 and 185b1, and an input and output pad I/O_PAD. The input and output pad I/O_PAD may be configured to electrically connect the semiconductor memory device to an external device, according to some embodiments. As used herein, the cell substrate 100C may also be referred to as a first substrate, and the peripheral substrate 100P may also be referred to as a second substrate. As used herein, the input and output pad I/O_PAD may also be referred to as an input/output (I/O) pad.

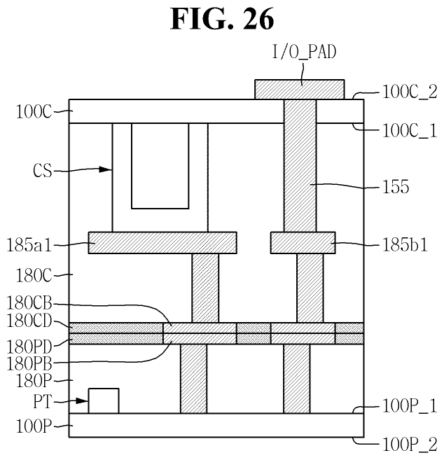

Referring to FIGS. 26 to 33, the semiconductor memory device according to some embodiments may further include a first bonding metal 180CB, a second bonding metal 180PB, a first bonding insulating film 180CD, and a second bonding insulating film 180PD. The cell substrate 100C and the peripheral substrate 100P may be copper-to-copper (Cu—Cu) bonded by the first bonding metal 180CB, the second bonding metal 180PB, the first bonding insulating film 180CD, and the second bonding insulating film 180PD.

The same explanation of the capacitor structure CS explained with reference to FIG. 2 may be applied to the capacitor structure CS. The same explanation of the peripheral contact plug 155 explained with reference to FIG. 2 may be applied to the peripheral contact plug 155. The same explanation of the first and second wiring lines 185a and 185b explained with reference to FIG. 2 may be applied to the first and second wiring lines 185a1 and 185b1.

The first and second wiring lines 185a1 and 185b1 may be located at the same level. The first and second wiring lines 185a1 and 185b1 may have the same thickness. The first and second wiring lines 185a1 and 185b1 may be formed simultaneously (i.e., concurrently) in the same process.

The cell substrate 100C may include a first surface 100C_1 on which the capacitor structure CS is formed, and a second surface 100C_2 opposite to the first surface 100C_1. The peripheral substrate 100P may include a third surface 100P_1 on which peripheral circuit elements PT are formed, and a fourth surface 100P_2 opposite to the third surface 100P_1.

Referring to FIGS. 18 to 33, the semiconductor memory device according to some embodiments may include a Cell-On-Peri (COP) structure in which the cell substrate 100C is disposed on the peripheral substrate 100P.

Referring to FIG. 18, the first surface 100C_1 of the cell substrate 100C and the third surface 100P_1 of the peripheral substrate 100P may face each other. The input and output pad I/O_PAD may be disposed on the cell substrate 100C.

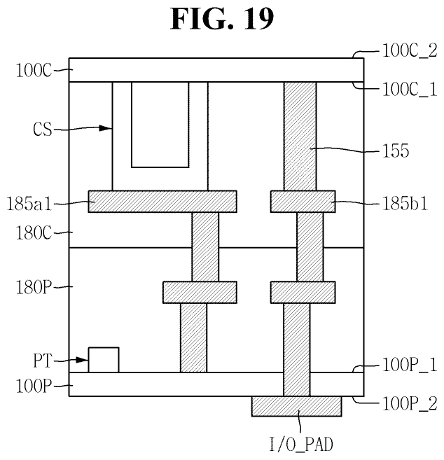

Referring to FIG. 19, the first surface 100C_1 of the cell substrate 100C and the third surface 100P_1 of the peripheral substrate 100P may face each other. The input and output pad I/O_PAD may be disposed on the peripheral substrate 100P.

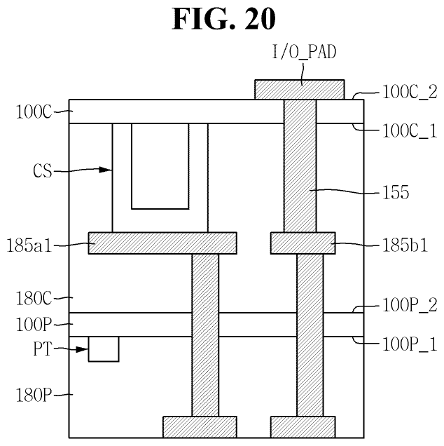

Referring to FIG. 20, the first surface 100C_1 of the cell substrate 100C and the fourth surface 100P_2 of the peripheral substrate 100P may face each other. The input and output pad I/O_PAD may be disposed on the cell substrate 100C.

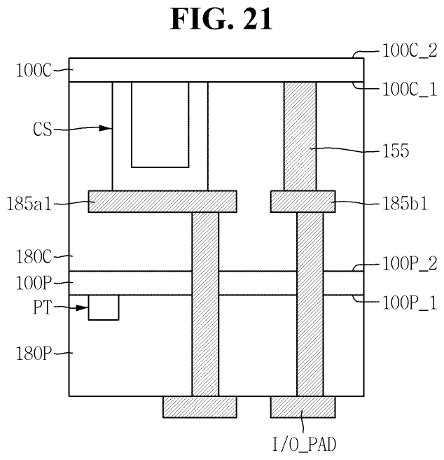

Referring to FIG. 21, the first surface 100C_1 of the cell substrate 100C and the fourth surface 100P_2 of the peripheral substrate 100P may face each other. The input and output pad I/O_PAD may be disposed on the peripheral insulating film 180P.

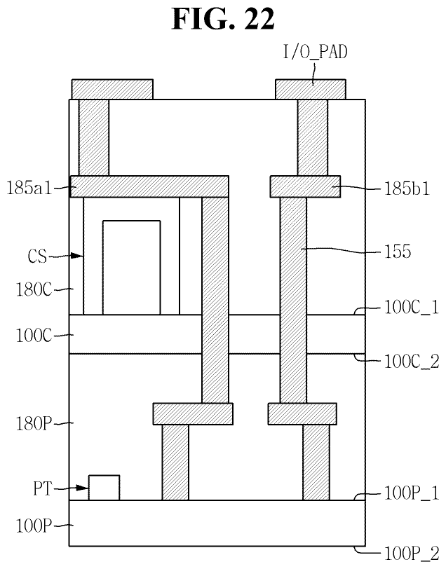

Referring to FIG. 22, the second surface 100C_2 of the cell substrate 100C and the third surface 100P_1 of the peripheral substrate 100P may face each other. The input and output pad I/O_PAD may be disposed on the cell insulating film 180C.

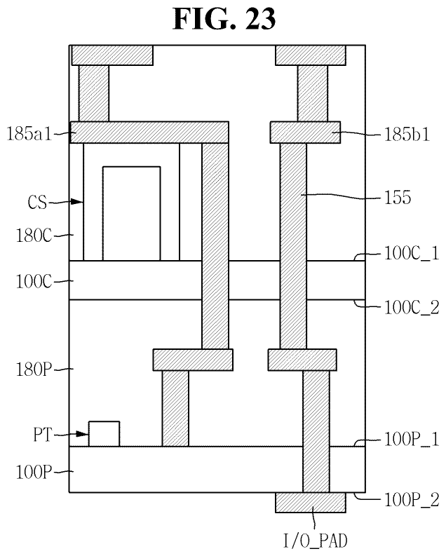

Referring to FIG. 23, the second surface 100C_2 of the cell substrate 100C and the third surface 100P_1 of the peripheral substrate 100P may face each other. The input and output pad I/O_PAD may be disposed on the peripheral substrate 100P.

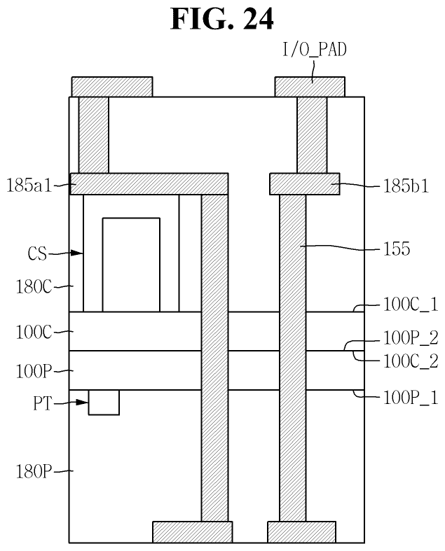

Referring to FIG. 24, the second surface 100C_2 of the cell substrate 100C and the fourth surface 100P_2 of the peripheral substrate 100P may be bonded to face each other. The input and output pad I/O_PAD may be disposed on the cell insulating film 180C.

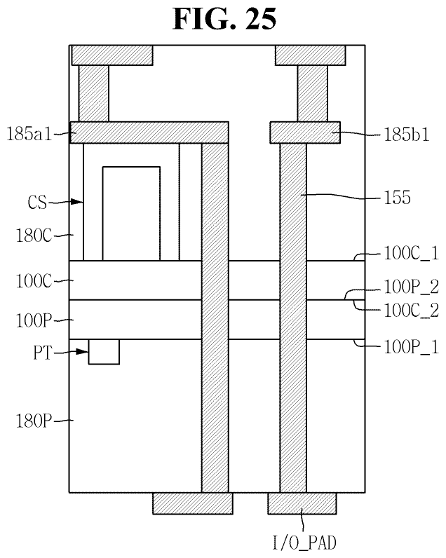

Referring to FIG. 25, the second surface 100C_2 of the cell substrate 100C and the fourth surface 100P_2 of the peripheral substrate 100P may be bonded to face each other. The input and output pad I/O_PAD may be disposed on the peripheral insulating film 180P.

Referring to FIG. 26, the first surface 100C_1 of the cell substrate 100C and the third surface 100P_1 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the cell substrate 100C.

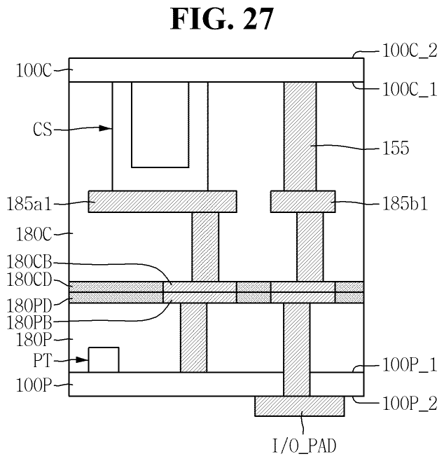

Referring to FIG. 27, the first surface 100C_1 of the cell substrate 100C and the third surface 100P_1 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the peripheral substrate 100P.

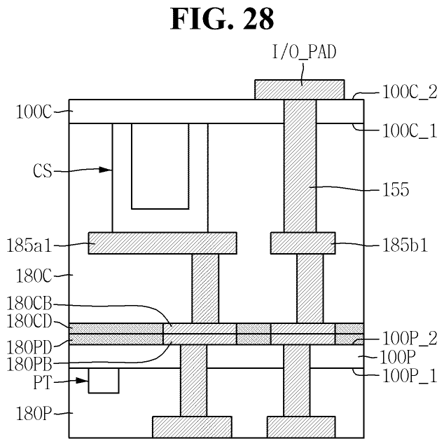

Referring to FIG. 28, the first surface 100C_1 of the cell substrate 100C and the fourth surface 100P_2 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the cell substrate 100C.

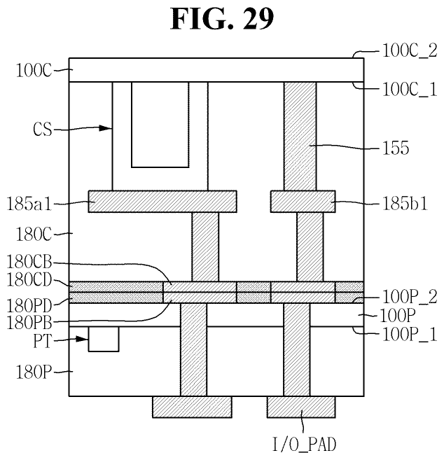

Referring to FIG. 29, the first surface 100C_1 of the cell substrate 100C and the fourth surface 100P_2 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the peripheral insulating film 180P.

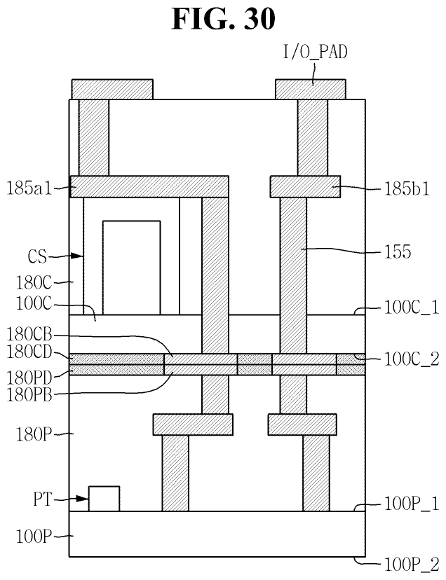

Referring to FIG. 30, the second surface 100C_2 of the cell substrate 100C and the third surface 100P_1 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the cell insulating film 180C.

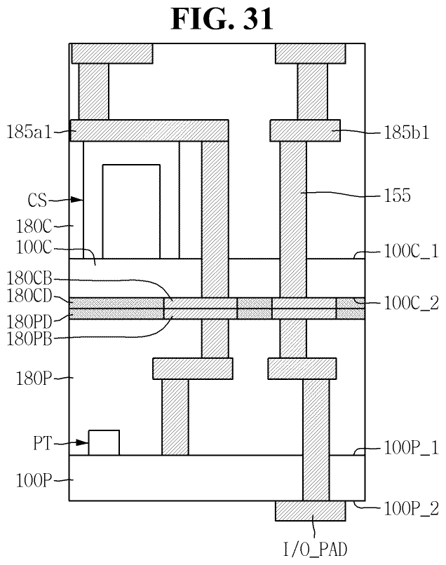

Referring to FIG. 31, the second surface 100C_2 of the cell substrate 100C and the third surface 100P_1 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the peripheral substrate 100P.

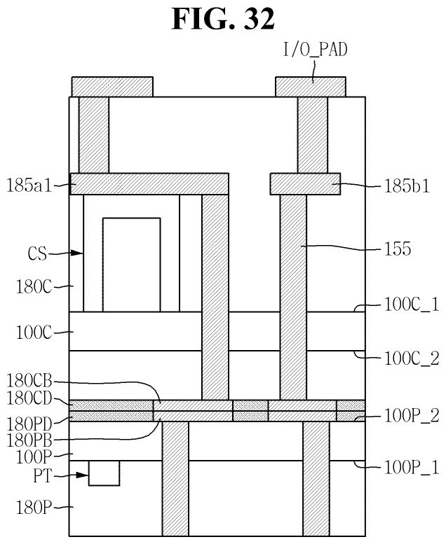

Referring to FIG. 32, the second surface 100C_2 of the cell substrate 100C and the fourth surface 100P_2 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the cell insulating film 180C.

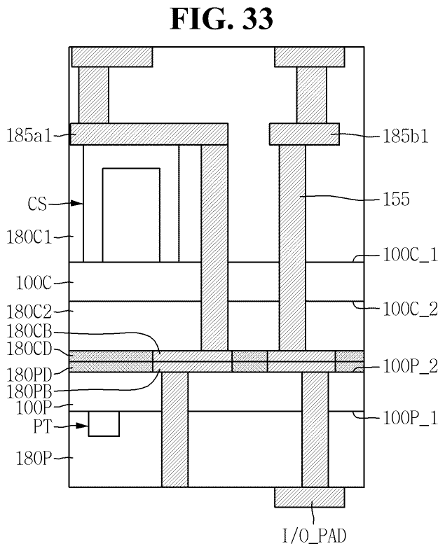

Referring to FIG. 33, the second surface 100C_2 of the cell substrate 100C and the fourth surface 100P_2 of the peripheral substrate 100P may face each other. The cell substrate 100C and the peripheral substrate 100P may be bonded to each other by the first bonding metal 180CB, the second bonding metal 180PB, the first bonding insulating film 180CD, and the second bonding insulating film 180PD interposed between the cell substrate 100C and the peripheral substrate 100P. The input and output pad I/O_PAD may be disposed on the peripheral insulating film 180P.

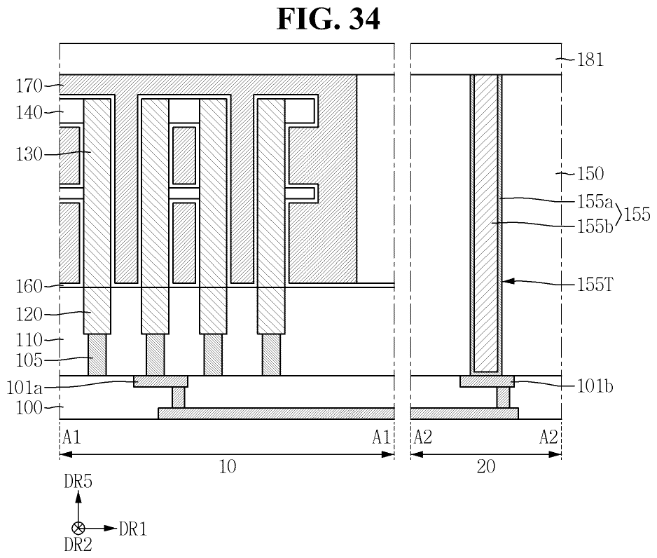

FIGS. 34 to 36 are intermediate stage diagrams for explaining a method of manufacturing a semiconductor memory device according to some embodiments. As an example, FIGS. 34 to 36 are diagrams showing a manufacturing method for forming the semiconductor memory device of FIG. 2.

Referring to FIG. 34, first, the substrate 100 including the cell pattern region 10 and the peripheral region 20 may be provided.

The capacitor structure (CS of FIG. 2) may be formed on the cell pattern region 10 of the substrate 100. The capacitor structure (CS of FIG. 2) may include a lower electrode 130 extending in the vertical direction DR5 perpendicular to the upper surface of the substrate 100, a capacitor dielectric film 160 extending along the lower electrode 130, and an upper electrode 170 on the capacitor dielectric film 160.

A second interlayer insulating film 150 that is on (e.g., that covers) the sidewalls of the upper electrode 170 may be formed on the substrate 100. The second interlayer insulating film 150 may be formed in the cell pattern region 10 and the peripheral region 20 of the substrate 100.

A peripheral contact plug trench 155T extending in the vertical direction DR5 may be formed in the second interlayer insulating film 150 of the peripheral region 20. The peripheral contact plug 155 may include a barrier layer 155a extending along the inner sidewall and bottom surface of the peripheral contact plug trench 155T, and a conductive layer 155b that fills the peripheral contact plug trench 155T on the barrier layer 155a. For example, the barrier layer 155a may include titanium nitride, and the conductive layer 155b may include tungsten.

In the drawings, the profile of the sidewall of the peripheral contact plug trench 155T is only shown as being perpendicular to the upper surface of the substrate 100, but the present disclosure is not limited thereto. For example, the peripheral contact plug trench 155T may be formed in a reversed trapezoidal shape.

By forming the barrier layer 155a and the conductive layer 155b, the peripheral contact plug 155 penetrating the second interlayer insulating film 150 in the vertical direction DR5 may be formed. The peripheral contact plug 155 may extend in the vertical direction DR5 in the second interlayer insulating film 150.

A planarization process may be performed on the upper surface of the upper electrode 170 and the upper surface of the peripheral contact plug 155. The planarization process may be, for example, a chemical mechanical polishing (CMP) process. The upper surfaces of the barrier layer 155a and the conductive layer 155b may be partially removed by the planarization process, and a third interlayer insulating film 181, which will be described later, may come into contact with the conductive layer 155b.

A third interlayer insulating film 181 may be formed on the cell pattern region 10 and the peripheral region 20. The third interlayer insulating film 181 may be formed on the upper electrode 170, the second interlayer insulating film 150, and the peripheral contact plug 155. The third interlayer insulating film 181 may be on (e.g., may cover) the upper surfaces of the upper electrode 170, the second interlayer insulating film 150, and the peripheral contact plug 155. The third interlayer insulating film 181 may include, for example, a low dielectric constant insulating material.

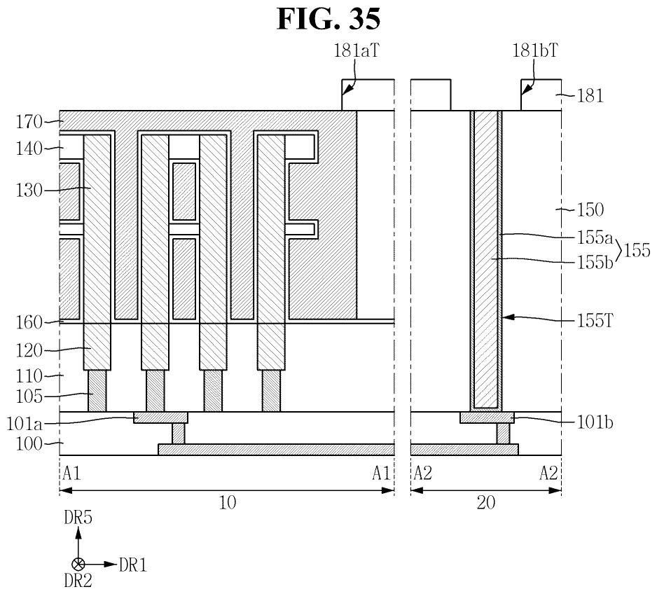

Referring to FIG. 35, first and second interlayer insulating film trenches 181aT and 181bT may be formed in the third interlayer insulating film 181, by removing a part of the third interlayer insulating film 181. Each of the first and second interlayer insulating film trenches 181aT and 181bT may expose at least a part of the upper surface of the upper electrode 170 and at least a part of the upper surface of the peripheral contact plug 155.

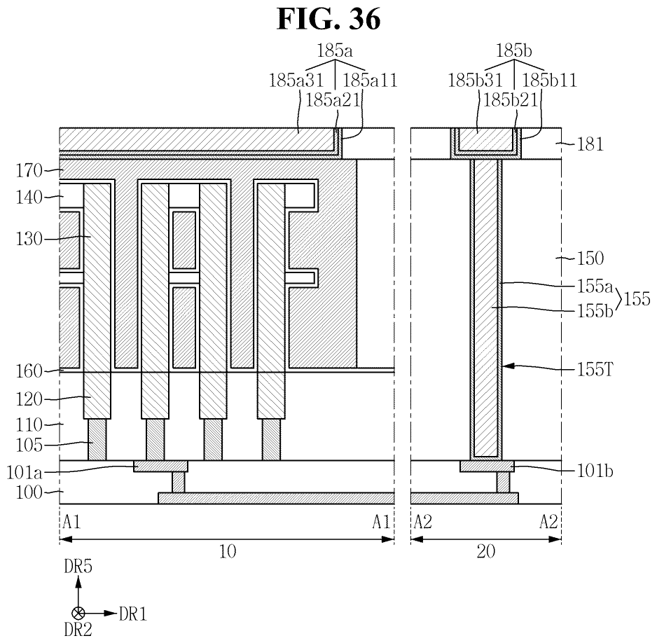

Referring to FIG. 36, first and second wiring lines 185a and 185b may be formed in the first and second interlayer insulating film trenches 181aT and 181bT, respectively.

The first wiring line 185a may be in contact with the upper electrode 170 on the upper electrode 170. The second wiring line 185b may be in contact with the peripheral contact plug 155 on the peripheral contact plug 155.

The first wiring line 185a may include a barrier layer 185a11, a seed layer 185a21, and a conductive layer 185a31, which are sequentially formed in the first interlayer insulating film trench 181aT. The barrier layer 185a11 and the seed layer 185a21 may extend along the inner sidewall and bottom surface of the first interlayer insulating film trench 181aT. The conductive layer 185a31 may fill the interior of the first interlayer insulating film trench 181aT.

The second wiring line 185b may include a barrier layer 185b11, a seed layer 185b21, and a conductive layer 185b31, which are sequentially formed in the second interlayer insulating film trench 181bT. The barrier layer 185b11 and the seed layer 185b21 may extend along the inner sidewall and bottom surface of the second interlayer insulating film trench 181bT. The conductive layer 185b31 may fill the interior of the second interlayer insulating film trench 181bT.

For example, the barrier layers 185a11 and 185b11 may include titanium nitride, the seed layers 185a21 and 185b21 may include copper, and the conductive layers 185a31 and 185b31 may include tungsten.

The first and second wiring lines 185a and 185b may be formed simultaneously (i.e., concurrently) by the same process. For example, each of the first and second wiring lines 185a and 185b may be formed by atomic layer deposition (ALD), chemical vapor deposition (CVD), physical vapor deposition (PVD), metal organic ALD (MOALD), metal organic CVD (MOCVD) or an electroplating process.

Thereafter, the planarization process may be performed on the first and second wiring lines 185a and 185b. The planarization process may be, for example, a chemical mechanical polishing (CMP) process. A part of the first and second wiring lines 185a and 185b may be removed by the planarization process, and the third interlayer insulating film 181 may be exposed.

Referring back to FIG. 2, thereafter, a fourth interlayer insulating film 182 may be formed on the first and second wiring lines 185a and 185b and the third interlayer insulating film 181. First and second wiring vias 186a and 186b and third and fourth wiring lines 187a and 187b may be formed in the fourth interlayer insulating film 182. Accordingly, a semiconductor memory device as shown in FIG. 2 may be formed.

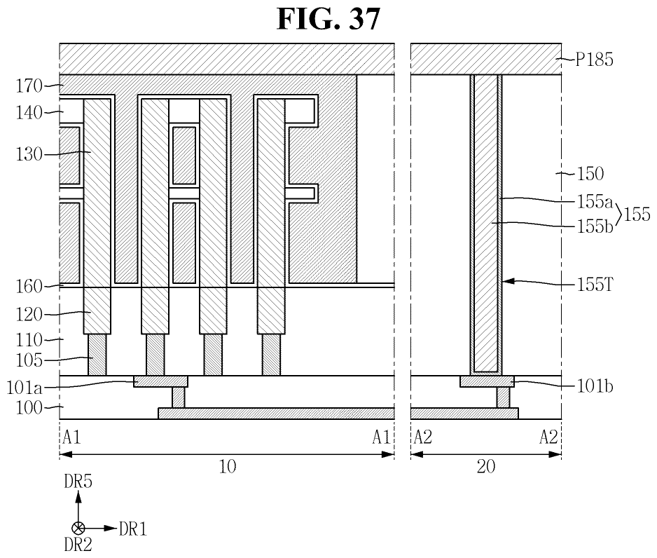

FIGS. 37 to 39 are intermediate stage diagrams for explaining a method of manufacturing a semiconductor memory device according to some embodiments. As an example, FIGS. 37 to 39 are diagrams showing a manufacturing method for forming the semiconductor memory device of FIG. 2. For convenience of explanation, the following description will mainly focus on points that are different from those explained with reference to FIGS. 34 to 36.

Referring to FIG. 37, a pre-metal layer P185 may be formed on the second interlayer insulating film 150, the upper electrode 170, and the peripheral contact plug 155. The pre-metal layer P185 may be on (e.g., may cover) the upper surfaces of the second interlayer insulating film 150, the upper electrode 170, and the peripheral contact plug 155. The pre-metal layer P185 may include, for example, tungsten.

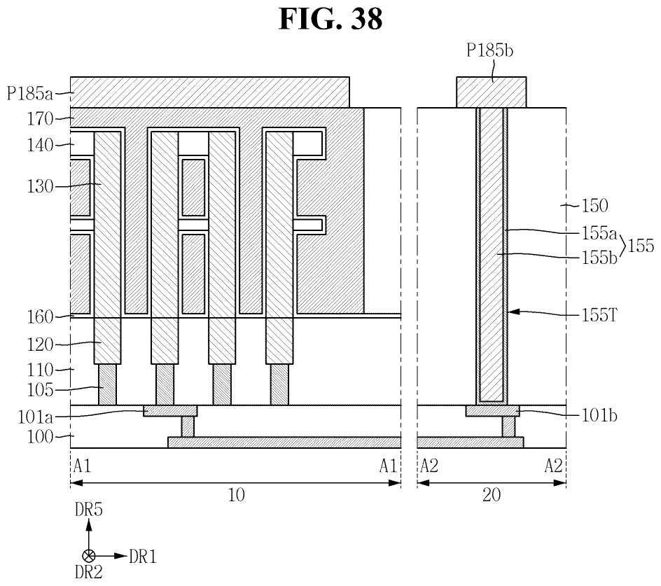

Referring to FIG. 38, a part of the upper surface of the second interlayer insulating film 150 may be exposed by removing a part of the pre-metal layer P185. First and second pre-wiring lines P185a and P185b spaced apart from each other may be formed by removing a part of the pre-metal layer P185. The first pre-wiring line P185a may be in contact with the upper electrode 170 on the upper electrode 170, and the second pre-wiring line P185b may be in contact with the peripheral contact plug 155 on the peripheral contact plug 155.

A part of the pre-metal layer P185 may be removed by a metal etching process.

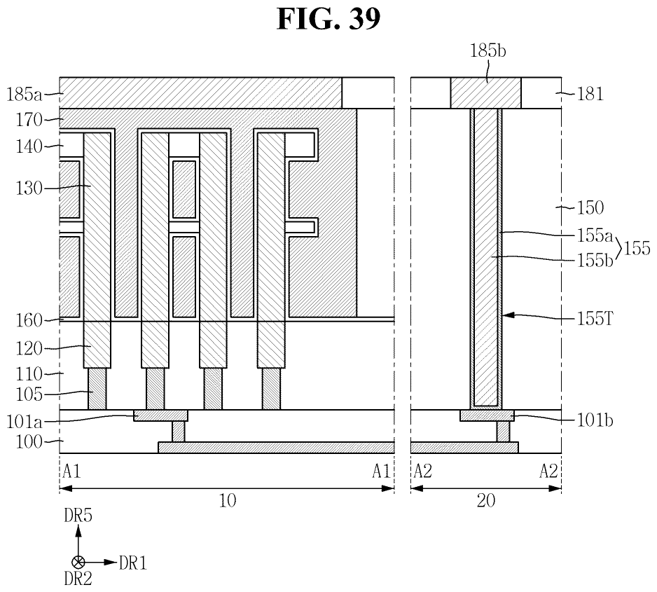

Referring to FIG. 39, a third interlayer insulating film 181 may be formed in the region in which the pre-metal layer P185 is removed. Thereafter, the planarization process may be performed on the third interlayer insulating film 181 and the first and second pre-wiring lines P185a and P185b. The planarization process may be, for example, a chemical mechanical polishing (CMP) process. The third interlayer insulating film 181 and the first and second pre-wiring lines P185a and P185b may be partially removed by the planarization process, and the first wiring line 185a and the second wiring line 185b may be formed on the upper electrode 170 and the peripheral contact plug 155, respectively.

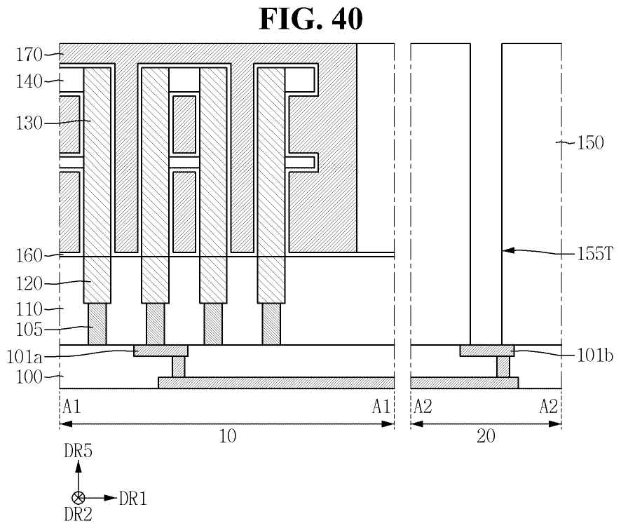

FIGS. 40 to 43 are intermediate stage diagrams for explaining a method of manufacturing a semiconductor memory device according to some embodiments. As an example, FIGS. 40 to 43 are diagrams showing a manufacturing method for forming the semiconductor memory device of FIG. 2. For convenience of explanation, the following description will mainly focus on points that are different from those explained with reference to FIGS. 37 to 39.

Referring to FIG. 40, a peripheral contact plug trench 155T extending in the vertical direction DR5 may be formed in the second interlayer insulating film 150 of the peripheral region 20. As the peripheral contact plug trench 155T is formed, at least a part of the upper surface of the second lower wiring line 101b may be exposed.

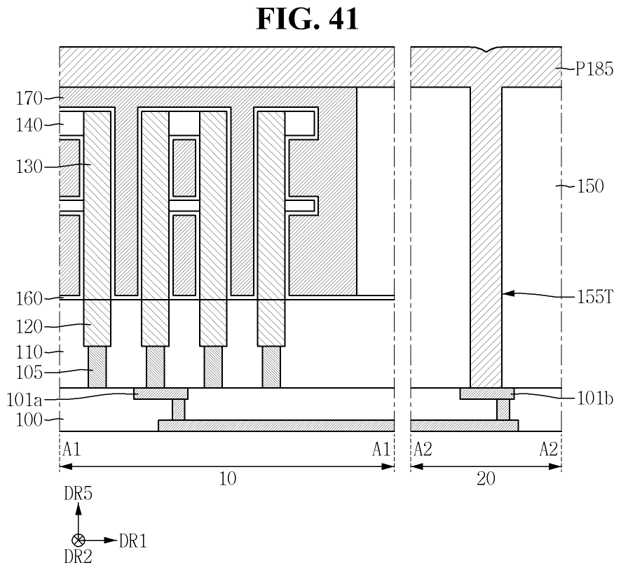

Referring to FIG. 41, the pre-metal layer P185 may be formed above the upper electrode 170, above the second interlayer insulating film 150, and in the peripheral contact plug trench 155T. The pre-metal layer P185 may be integrally formed above the second interlayer insulating film 150, above the upper electrode 170, and in the peripheral contact plug trench 155T. A recessed portion may be formed on the upper surface of the pre-metal layer P185 corresponding to the peripheral contact plug trench 155T, but the present disclosure is not limited thereto.

The pre-metal layer P185 may include, for example, at least one of titanium nitride, molybdenum, or tungsten.

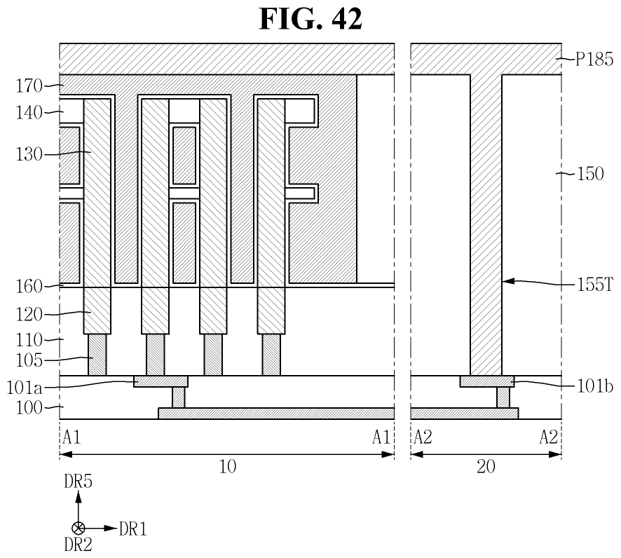

Referring to FIG. 42, the planarization process may be performed on the pre-metal layer P185. The planarization process may be, for example, a chemical mechanical polishing (CMP) process. A part of the pre-metal layer P185 may be removed by the planarization process.

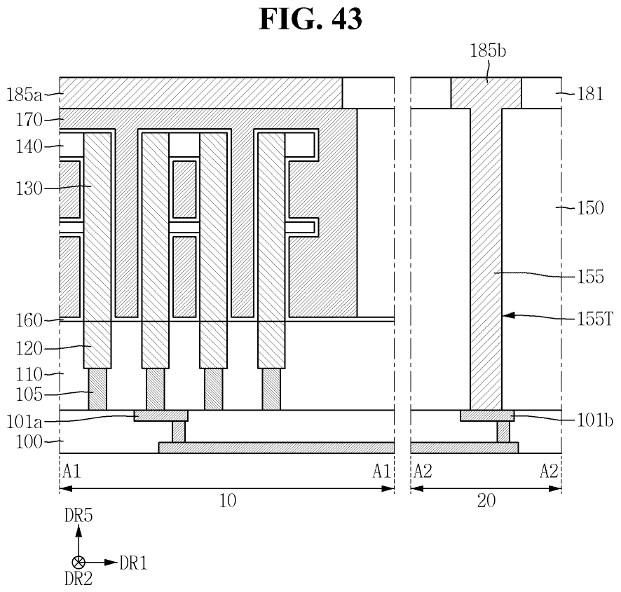

Referring to FIG. 43, each of the first and second pre-wiring lines P185a and P185b may be formed by removing a part of the pre-metal layer P185. A third interlayer insulating film 181 may be formed in the region in which the pre-metal layer P185 is removed, and first and second wiring lines 185a and 185b may be formed.

According to some embodiments, first and second wiring lines 185a and 185b may be formed on the upper electrode 170 and the peripheral contact plug 155, respectively, at the same time. In some embodiments, since the first wiring line 185a may be immediately formed without forming separate contacts on the upper electrode 170, it is possible to reduce resistance compared to a case of forming contacts on the upper electrode 170. Furthermore, since the height of the wiring may be reduced compared to the case of forming contacts, the difficulty of the process may be reduced.

Although example embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the scope of the present disclosure. Accordingly, the above-described embodiments should be understood in all respects as illustrative and not restrictive.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

1. A semiconductor memory device comprising:
a first substrate region that extends in a first direction and a second direction intersecting the first direction, the first substrate region comprising a cell region;
a second substrate region that extends in the first and second directions, the second substrate region comprising a peripheral region that is adjacent to the cell region;
a capacitor structure on the first substrate region, the capacitor structure comprising a lower electrode extending in a third direction perpendicular to an upper surface of the first substrate region, a capacitor dielectric film extending along the lower electrode, and an upper electrode on the capacitor dielectric film;
a first insulating layer that is on the first substrate region and is in contact with a sidewall of the upper electrode;
a peripheral contact plug that is on the second substrate region and extends in the first insulating layer in the third direction;
a first wiring line that is on the upper electrode and is in contact with the upper electrode; and
a second wiring line that is on the peripheral contact plug and is in contact with the peripheral contact plug,
wherein a thickness of the first wiring line is equal to a thickness of the second wiring line.

2. The semiconductor memory device of claim 1, wherein an upper surface of the upper electrode is coplanar with an upper surface of the peripheral contact plug.

3. The semiconductor memory device of claim 1, wherein the upper electrode comprises a recess, and the first wiring line is in the recess.

4. The semiconductor memory device of claim 3, wherein a lower surface of the first wiring line is closer to the first substrate region than an upper surface of the upper electrode is.

5. The semiconductor memory device of claim 3, wherein an upper surface of the first wiring line is coplanar with an upper surface of the upper electrode.

6. The semiconductor memory device of claim 1, wherein, in a plan view, the upper electrode surrounds the first wiring line, and
wherein the sidewall of the upper electrode protrudes beyond a sidewall of the first wiring line in the first direction.

7. The semiconductor memory device of claim 1, wherein at least a portion of the first wiring line does not overlap the upper electrode in the third direction, and
wherein a sidewall of the first wiring line protrudes beyond the sidewall of the upper electrode in the first direction.

8. The semiconductor memory device of claim 1, wherein the first wiring line overlaps the upper electrode in the third direction, and
wherein a sidewall of the first wiring line is coplanar with the sidewall of the upper electrode in the third direction.

9. The semiconductor memory device of claim 1, wherein, in a plan view, the first wiring line comprises a plurality of lines extending in the second direction and spaced apart from each other in the first direction.

10. The semiconductor memory device of claim 1, further comprising an input/output (I/O) pad electrically connected to the peripheral contact plug,
wherein the first substrate region comprises a first substrate, the first substrate including a first surface and a second surface opposite to the first surface,
wherein the capacitor structure is on the first surface of the first substrate,
wherein the second substrate region comprises a second substrate, the second substrate including a third surface and a fourth surface opposite to the third surface,
wherein the semiconductor memory device further comprises one or more peripheral circuit elements on the third surface of the second substrate, and
wherein the first substrate is on the second substrate.

11. The semiconductor memory device of claim 1, wherein each of the first and second wiring lines comprises at least one of metal, metal nitride, metal oxide, or metal silicide.

12. The semiconductor memory device of claim 1, wherein the first insulating layer comprises at least one of silicon oxide, silicon oxycarbide, silicon oxynitride, silicon carbonitride, or silicon boron nitride.

13. A semiconductor memory device comprising:
a first substrate region that extends in a first direction and a second direction intersecting the first direction, the first substrate region comprising a cell region;
a second substrate region that extends in the first and second directions, the second substrate region comprising a peripheral region that is adjacent to the cell region;
a capacitor structure on the first substrate region, the capacitor structure comprising a lower electrode extending in a third direction perpendicular to an upper surface of the first substrate region, a capacitor dielectric film extending along the lower electrode, and an upper electrode on the capacitor dielectric film;
a first insulating layer that is on the first substrate region and is in contact with a sidewall of the upper electrode;
a peripheral contact plug that is on the second substrate region and extends in the first insulating layer in the third direction;
a first wiring line that is on the upper electrode and is in contact with the upper electrode;
a second wiring line that is on the peripheral contact plug and is in contact with the peripheral contact plug;
a first wiring via on the first wiring line; and
a second wiring via on the second wiring line,
wherein the first and second wiring lines are located at a same level as each other in the third direction relative to the upper surface of the first substrate region, and
wherein the first and second wiring vias are located at a same level as each other in the third direction relative to the upper surface of the first substrate region.

14. The semiconductor memory device of claim 13, wherein, in a plan view, the upper electrode surrounds the first wiring via.

15. The semiconductor memory device of claim 13, wherein the first wiring via does not overlap the upper electrode in the third direction.

16. The semiconductor memory device of claim 13, further comprising:
a landing pad electrically connected to the lower electrode;
a first lower wiring line in the first substrate region and electrically connected to the landing pad; and
a second lower wiring line in the second substrate region and electrically connected to the peripheral contact plug.

17. The semiconductor memory device of claim 13, wherein the first and second wiring lines comprise a same material.

18. A method of manufacturing a semiconductor memory device, the method comprising:
providing a substrate that extends in a first direction and a second direction intersecting the first direction, the substrate comprising a first region and a second region;
forming a capacitor structure on the first region of the substrate, the capacitor structure comprising a lower electrode extending in a third direction perpendicular to an upper surface of the substrate, a capacitor dielectric film extending along the lower electrode, and an upper electrode on the capacitor dielectric film;
forming a first insulating layer on the substrate, the first insulating layer contacting a sidewall of the upper electrode;
forming a peripheral contact plug on the second region of the substrate, the peripheral contact plug extending in the first insulating layer in the third direction; and
concurrently forming a first wiring line on the upper electrode and a second wiring line on the peripheral contact plug,
wherein the first wiring line is in contact with the upper electrode, and the second wiring line is in contact with the peripheral contact plug.

19. The method of claim 18, wherein concurrently forming the first wiring line and the second wiring line comprises:
forming a second insulating layer on the first insulating layer, the upper electrode, and the peripheral contact plug;
removing portions of the second insulating layer to form a first trench and a second trench; and
forming the first wiring line and the second wiring line in the first trench and the second trench, respectively.

20. The method of claim 18, wherein concurrently forming the first wiring line and the second wiring line comprises:
forming a pre-metal layer on the first insulating layer, the upper electrode, and the peripheral contact plug; and
removing portions of the pre-metal layer to form the first wiring line and the second wiring line.

21-23. (canceled)
